(19) United States
(12) Patent Application Publication
(10) Pub. No.: US 2019/0284436 A1
(43) Pub. Date: Sep. 19, 2019

(54) COMPOSITION AND METHOD FOR TREATING SEMICONDUCTOR SURFACE

(71) Applicant: JSR CORPORATION, Minato-ku (JP)

(72) Inventors: Kiyotaka MITSUMOTO, Minato-ku (JP); Hidenori NARUSE, Minato-ku (JP); Takuya MIURA, Minato-ku (JP)

(73) Assignee: JSR CORPORATION, Minato-ku (JP)

(21) Appl. No.: 16/353,130

(22) Filed: Mar. 14, 2019

(30) Foreign Application Priority Data
Mar. 14, 2018 (JP) 2018-046479

(51) Int. Cl. C09G 1/16; C08K 5/092; C08K 5/17; C08K 5/3445; C09G 1/18; H01L 21/321; H01L 21/02

(52) U.S. Cl. CPC C09G 1/16; C08K 5/092; C08K 5/175; H01L 21/02074; C08K 5/17; C09G 1/18; H01L 21/3212; C08K 5/3445

(57) ABSTRACT

A composition for treating a surface of semiconductor is provided by (A) a polymer having a polymer chain having a repeating unit represented by the following Formula (1); and (B) a chelating agent having a molecular weight of 500 or less:

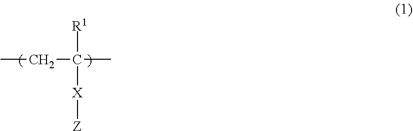

wherein R¹ represents a hydrogen atom or a methyl group; Z represents a group forming an organic ammonium salt, —NR⁵R⁶ (wherein R⁵ and R⁶ each independently represent a hydrogen atom, or a substituted or unsubstituted hydrocarbon group), or a substituted or unsubstituted nitrogen-containing heterocyclic group; and X represents a single bond or a divalent linking group.

### BACKGROUND

The present invention relates to a composition for treating a surface of semiconductor and a method for treating a surface of semiconductor using the composition.

### RELATED ART

Chemical mechanical polishing (CMP) has been popularized in, for example, flattening technologies used for the production of semiconductor devices. A slurry for chemical mechanical polishing used for CMP includes polishing particles (abrasive grains) as well as, for example, an etching agent. In the production of a semiconductor device, after the CMP process, in order to eliminate contaminants such as polishing debris or organic residue from the surface, a process of cleaning a semiconductor with a cleaning composition is also essential.

Since metal wiring materials such as tungsten and cobalt are exposed on the surface of a semiconductor substrate, it is necessary that CMP or any subsequent cleaning is carried out so as not to give damage such as corrosion to the surface to be polished where such a metal wiring material is exposed. Regarding technologies for suppressing damage to such a surface to be polished, for example, use of a composition for chemical mechanical polishing including polyethyleneimine (JP 2016-524324 A) or use of a composition for semiconductor substrate cleaning including polyallylamine (JP 2012-33774 A) has been suggested.

### SUMMARY OF THE INVENTION

However, in recent years, along with micronization of circuit structures, there is a demand to further suppress damage to metal wirings of semiconductor. Meanwhile, it has been difficult to meet this demand together with a demand for effective reduction or removal of contaminations.

Therefore, it is an object of the present invention to provide a composition for treating a surface of semiconductor, the composition being capable of effectively reducing or removing contaminations from the surface of a semiconductor when used for treatments such as polishing and cleaning, and being not likely to corrode a metal material such as metal wiring; and a method of using this composition.

The object of the present invention has been solved by the following means <1> to <8>.

<1> A composition for treating a surface of semiconductor (hereinafter, also referred to as “composition for treating a surface of semiconductor of the invention”), including: (A) a polymer (hereinafter, also referred to as “particular polymer”) having a polymer chain (hereinafter, also referred to as “particular polymer chain”) having a repeating unit represented by the following Formula (1) (hereinafter, also referred to as “repeating unit (1)”); and (B) a chelating agent having a molecular weight of 500 or less:

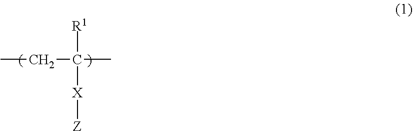

wherein R¹ represents a hydrogen atom or a methyl group; Z represents a group forming an organic ammonium salt, —NR⁵R⁶ (provided that R⁵ and R⁶ each independently represent a hydrogen atom, or a substituted or unsubstituted hydrocarbon group), or a substituted or unsubstituted nitrogen-containing heterocyclic group; and X represents a single bond or a divalent linking group.

<2> The composition according to <1>, wherein the (A) polymer further has a partial structure (provided that the polymer chain is excluded; furthermore, hereinafter, this partial structure will also be referred to as “particular partial structure”) derived from a compound containing a group represented by —NH— (hereinafter, also referred to as “particular functional group”).

<3> The composition according to <2>, wherein the partial structure is a residue by removing a part of or all of hydrogen atoms derived from the group represented by —NH—, from the compound containing a group represented by —NH—.

<4> The composition according to any one of <1> to <3>, wherein the (B) chelating agent is at least one selected from the group consisting of an organic amine-based chelating agent having a molecular weight of 500 or less, and an organic acid-based chelating agent having two or more carboxyl groups and having a molecular weight of 500 or less.

<5> The composition according to any one of <1> to <4>, wherein the pH at 25° C. is 2 to 6.

<6> The composition according to any one of <1> to <4>, wherein the pH at 25° C. is 8 to 10.

<7> A method for treating a surface of semiconductor (hereinafter, also referred to as “method for treating a surface of semiconductor of the invention”), using the composition according to any one of <1> to <6>.

<8> The method according to <7>, wherein a substrate of the semiconductor is a semiconductor substrate including tungsten.

The composition for treating a surface of semiconductor of the invention is not likely to corrode a metal material such as metal wiring, and has an effect of effectively reducing or removing contaminations from the surface of a semiconductor, when used for treatments such as polishing and cleaning. Furthermore, when the composition is used for a polishing treatment, the composition is not likely to decrease the polishing speed.

According to the method for treating a surface of semiconductor of the invention, a semiconductor with reduced contaminations or metal corrosion can be obtained.

### BRIEF DESCRIPTION OF DRAWINGS

FIG. 1 is a cross-sectional view schematically illustrating a production process for a wiring substrate by utilizing the method for treating a surface of semiconductor of the present invention.

### DETAILED DESCRIPTION

[Composition for Treating a Surface of Semiconductor]

The composition for treating a surface of semiconductor of the present invention includes (A) a polymer having a polymer chain having a repeating unit represented by Formula (1) described above; and (B) a chelating agent having a molecular weight of 500 or less.

<Component (A)>

Component (A) is a polymer having a polymer chain having a repeating unit represented by Formula (1) described above.

(Repeating Unit (1))

The repeating unit (1) is represented by Formula (1).

In Formula (1), Z represents a group forming an organic ammonium salt, —NR⁵R⁶, or a substituted or unsubstituted nitrogen-containing heterocyclic group.

Examples of the group forming an organic ammonium salt include —N⁺R²R³R⁴Y^{y-}, —(C═O)O⁻N+HR²R³R⁴, —(C═O)O⁻A⁺, and —OP (═O) (—O⁻) OC₂H₄N⁺R²R³R⁴ (provided that R² to R⁴ each independently represent a hydrogen atom, or a substituted or unsubstituted hydrocarbon group; Y^{y-} represents a y-valent counter anion; and A⁺ represents a quaternary ammonium cation), and —N⁺R²R³R⁴Y^{y-} is preferred.

R² to R⁶ each independently represent a hydrogen atom, or a substituted or unsubstituted hydrocarbon group. Here, the “hydrocarbon group” according to the invention is a concept including an aliphatic hydrocarbon group, an alicyclic hydrocarbon group, and an aromatic hydrocarbon group. The “hydrocarbon group” may be in any one of a linear form, a branched form, and a cyclic form, and the hydrocarbon group may be a saturated hydrocarbon group or an unsaturated hydrocarbon group, and may have an unsaturated bond at any of a terminal site or a non-terminal site.

The aliphatic hydrocarbon group is preferably an alkyl group having 1 to 20 carbon atoms (preferably 1 to 12 carbon atoms). Specific examples include a methyl group, an ethyl group, an n-propyl group, an isopropyl group, an n-butyl group, an isobutyl group, a sec-butyl group, and a tert-butyl group. The alicyclic hydrocarbon group is preferably an alicyclic hydrocarbon group having 3 to 20 carbon atoms (preferably 3 to 12 carbon atoms), and more preferably a cycloalkyl group having 3 to 20 carbon atoms (preferably 3 to 12 carbon atoms). Specific examples include a cyclopropyl group, a cyclobutyl group, a cyclopentyl group, and a cyclohexyl group. Furthermore, the aromatic hydrocarbon group is preferably an aromatic hydrocarbon group having 6 to 20 carbon atoms (preferably 6 to 10 carbon atoms), and more preferably an aryl group having 6 to 20 carbon atoms (preferably 6 to 10 carbon atom) or an aralkyl group having 7 to 20 carbon atoms (preferably 7 to 16 carbon atoms). Here, the “aryl group” according to the invention means a monocyclic to tricyclic aromatic hydrocarbon group, and examples include a phenyl group, a naphthyl group, a biphenyl group, and an anthranyl group. Specific examples of the aralkyl group include a benzyl group, a phenethyl group, an α-methylbenzyl group, and a 2-phenylpropan-2-yl group.

Among these, the hydrocarbon group for R² to R⁶ is preferably an alkyl group having 1 to 12 carbon atoms (more preferably 1 to 6 carbon atoms, and particularly preferably 1 to 4 carbon atoms) or an aralkyl group having 7 to 16 carbon atoms (more preferably 7 to 12 carbon atoms, and particularly preferably 7 to 9 carbon atoms) in order to enable further suppression of metal corrosion, and a methyl group, an ethyl group, an n-propyl group, an isopropyl group, an n-butyl group, an isobutyl group, a sec-butyl group, a tert-butyl group, and a benzyl group are particularly preferred.

Examples of a substituent for R² to R⁶ include an alkyl group having 1 to 6 carbon atoms, a halogen atom, a hydroxyl group, a benzoyl group, a substituted or unsubstituted amino group, a nitro group, a cyano group, a carboxyl group, and an alkoxy group having 1 to 6 carbon atoms.

Y^{y-} may be a monovalent counter anion or a polyvalent counter anion. Furthermore, Y^{y-} may be a monoatomic anion or a polyatomic anion.

A polyvalent counter anion may be an anion derived from a polyvalent anionic compound. A polyvalent anionic compound means an organic or inorganic compound that is ionized when dissolved in water and acquires a divalent or higher-valent negative charge. Examples of the polyvalent anionic compound include gums, polymer compounds such as a polyacrylic acid derivative, citric acid and salts thereof, and compounds known as chelating agents such as EDTA.

Examples of the monovalent counter anion include halogen ions such as Cl⁻, Br⁻, and I⁻; and acid counter anions such as ClO₄⁻, BF₄⁻, CH₃(C═O)O⁻, and PF₆⁻.

Y^{y-} is preferably a monovalent to hexavalent counter anion (y represents an integer from 1 to 6), more preferably a monovalent to trivalent counter anion (y represents an integer from 1 to 3), even more preferably a monovalent counter anion, and particularly preferably a halogen ion.

The “nitrogen-containing heterocyclic group” according to the invention refers to a heterocyclic group having at least one nitrogen atom as a constituent element of the ring, and the nitrogen-containing heterocyclic group is preferably a heterocyclic monocyclic group or a condensed heterocyclic group formed by two of those heterocyclic monocyclic groups being condensed together. These heterocyclic groups may have an unsaturated ring or a saturated ring, or may have a heteroatom other than a nitrogen atom (for example, an oxygen atom or a sulfur atom) in the ring.

Examples of the unsaturated heterocyclic ring include a pyridine ring, an imidazole ring, a thiazole ring, an oxazole ring, a triazole ring, a tetrazole ring, an imidazoline ring, and a tetrahydropyrimidine ring. Examples of the saturated heterocyclic ring include a morpholine ring, a piperidine ring, a piperazine ring, and a pyrrolidine ring. Furthermore, examples of a substituent for the nitrogen-containing heterocyclic group include an alkyl group having 1 to 6 carbon atoms, a halogen atom, a carboxyl group, an ester group, an ether group, a hydroxyl group, an amino group, an amide group, a thiol group, and a thioether group.

The heterocyclic monocyclic group is preferably a group having a 5-membered to 7-membered ring, and specific examples include groups having basic skeletons represented by the following Formula (1-1) and Formula (1-2). These heterocyclic monocyclic groups may have a substituent.

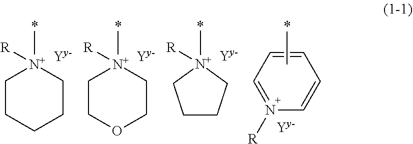

In Formula (1-1), R represents a hydrogen atom, or a substituted or unsubstituted hydrocarbon group; Y^{y-} represents a y-valent counter anion; and the symbol “*” represents a linking bond. However, examples of the hydrocarbon group for R include the same hydrocarbon groups for R², and examples of Y^{y-} include the same groups for Y^{y-} in N⁺R²R³R⁴Y^{y-}.

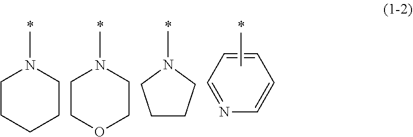

In Formula (1-2), the symbol “*” represents a linking bond.

Specific examples of the condensed heterocyclic group include groups having basic skeletons represented by the following Formulae (1-3) to (1-5), and these condensed heterocyclic groups may each have a substituent.

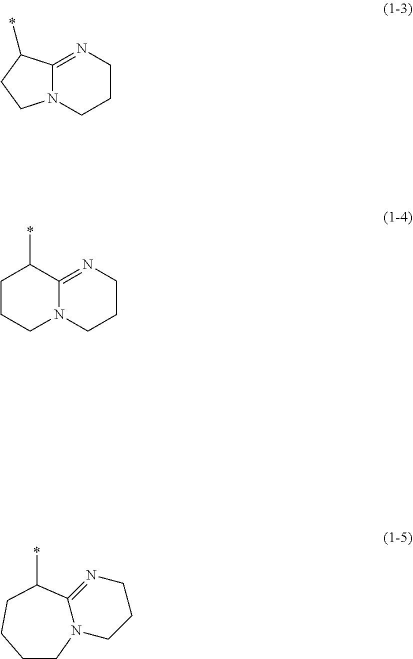 [SMILES: *C1CCN2CCCN=C12 ; *C1CCCN2CCCN=C12 ; *C1CCCCN2CCCN=C12]

In Formulae (1-3) to (1-5), the symbol “*” represents a linking bond.

Examples of the divalent linking group represented by X in Formula (1) described above include a methylene group, an alkylene group, an arylene group, —(C═O)OR¹¹-(*), —(C═O)NHR¹²-(*), and —ArR¹³— (*) (provided that Ar represents an arylene group; and the symbol “*” represents a linking bond for bonding to Z). Examples of the “arylene group” according to the invention include a phenylene group, a naphthylene group, and a phenanthrenylene group. R¹¹ to R¹³ each independently represent a methylene group, an alkylene group, and an alkyleneoxyalkylene group.

The alkylene group represented by X and R¹¹ to R¹³ is preferably an alkylene group having 2 to 10 carbon atoms (preferably 2 to 6 carbon atoms, and more preferably 2 to 4 carbon atoms). The alkylene group may be a linear group or a branched group, and specific examples include an ethylene group, a propylene group, a trimethylene group, a tetramethylene group, a pentamethylene group, and a hexamethylene group.

The alkylene group included in the alkyleneoxyalkylene group is preferably the same alkylene group as the above-mentioned alkylene group. The alkyleneoxyalkylene group is preferably a C₂₋₄ alkyleneoxy-C₂₄ alkylene group, and specific examples include an ethyleneoxyethylene group.

From the viewpoint that the selectivity for a side-chain introduction reaction is improved, and a particular polymer can be easily produced, X is preferably —(C═O)OR¹¹-(*), —(C═O)NHR¹²— (*), or —ArR¹³— (*), and particularly preferably —(C═O) OR¹¹— (*). R¹¹ to R¹³ are each particularly preferably an alkylene group having 2 to 6 carbon atoms (more preferably 2 to 4 carbon atoms).

(Repeating Unit (2))

It is preferable that the particular polymer chain has a repeating unit represented by the following Formula (2) (hereinafter, also referred to as “repeating unit (2)”) in addition to the repeating unit (1), in order to enhance desired effects.

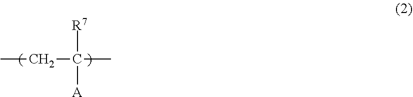

wherein R⁷ represents a hydrogen atom or a methyl group; and

A represents an aromatic hydrocarbon group, —(C═O)OR⁸, —(C═O)NHR⁹, or —OR¹⁰ (provided that R⁸ to R¹⁰ each represent a hydrocarbon group or a group having a chain or cyclic ether structure.

In regard to A of Formula (2), the aromatic hydrocarbon group is preferably an aryl group having 6 to 20 carbon atoms (preferably 6 to 10 carbon atoms), and particularly preferably a phenyl group.

In regard to A of Formula (2), R⁸ to R¹⁰ each represent a hydrocarbon group or a group having a chain or cyclic ether structure. Examples of the hydrocarbon group include, in addition to the hydrocarbon groups similar to those for R², alicyclic hydrocarbon groups such as a saturated condensed polycyclic hydrocarbon group, a saturated bridged-ring hydrocarbon group, a saturated spiro hydrocarbon group, and a saturated cyclic terpene hydrocarbon group. The hydrocarbon group for R⁵ to R¹⁰ is preferably an alkyl group having 1 to 20 carbon atoms (preferably 1 to 15 carbon atoms), an aryl group having 6 to 20 carbon atoms (preferably 6 to 14 carbon atoms), an aralkyl group having 7 to 20 carbon atoms (preferably 7 to 16 carbon atoms), or an alicyclic hydrocarbon group having 3 to 20 carbon atoms (preferably 4 to 15 carbon atoms). A methyl group, an ethyl group, an n-propyl group, an isopropyl group, an n-butyl group, an isobutyl group, a sec-butyl group, a tert-butyl group, a 2-ethylhexyl group, an isodecyl group, a dodecyl group, a phenyl group, a benzyl group, a phenylethyl group, a cyclohexyl group, a cyclohexenyl group, a t-butylcyclohexyl group, a decahydro-2-naphthyl group, a tricycle[5.2.1.0^{2,6}]decan-8-yl group, an adamantyl group, a dicyclopentenyl group, a pentacyclopentadecanyl group, a tricyclopentenyl group, and an isobornyl group are particularly preferred.

Meanwhile, the group having a chain ether structure for R⁸ to R¹⁰ is preferably a group represented by the following Formula (3).

*R¹⁴OₙR¹⁵ (3)

wherein R¹⁴ each independently represent an alkylene group having 2 to 4 carbon atoms;

R¹⁵ represents a hydrogen atom, an alkyl group having 1 to 6 carbon atoms, or a substituted or unsubstituted aryl group;

n represents an integer from 2 to 150; and

the symbol “*” represents a linking bond.

R¹⁴ may be configured to include two or more kinds of alkylene groups, and an ethylene group and/or a propylene group is preferred.

The alkyl group having 1 to 6 carbon atoms for R¹⁵ is preferably an alkyl group having 1 to 4 carbon atoms, and more preferably an alkyl group having 1 or 2 carbon atoms. The alkyl group may be a linear group or a branched group, and examples include a methyl group, an ethyl group, an n-propyl group, an isopropyl group, an n-butyl group, an isobutyl group, a sec-butyl group, and a tert-butyl group.

The aryl group for R¹⁵ is preferably a phenyl group. The aryl group may be substituted with, for example, an α-cumyl group.

R¹⁵ is preferably a hydrogen atom or an alkyl group having 1 to 6 carbon atoms.

n is preferably an integer from 2 to 20, more preferably an integer from 2 to 10, and particularly preferably an integer from 2 to 5.

Furthermore, the group having a cyclic ether structure for R⁸ to R¹⁰ is preferably a group represented by the following Formula (4).

*—R¹⁶—CE (4)

wherein R¹⁶ represents a methyl group or an alkylene group having 2 to 12 carbon atoms;

CE represents a cyclic ether group which may have an alkyl group as a substituent; and

the symbol “*” represents a linking bond.

In Formula (4), R¹⁶ is preferably a methylene group or an alkylene group having 2 to 6 carbon atoms. The alkylene group may be a linear group or a branched group. Specific examples of R¹⁶ include a methylene group, an ethylene group, an ethane-1,1-diyl group, a trimethylene group, a propane-1,1-diyl group, a propane-1,2-diyl group, a propane-2,2-diyl group, a tetramethylene group, a butane-1,2-diyl group, a butane-1,3-diyl group, a pentamethylene group, and a hexamethylene group.

In Formula (4), CE is preferably a cyclic ether group in which the number of atoms that constitute the ring is 3 to 7, and specific examples thereof include cyclic ether groups represented by the following Formulae (i) to (viii).

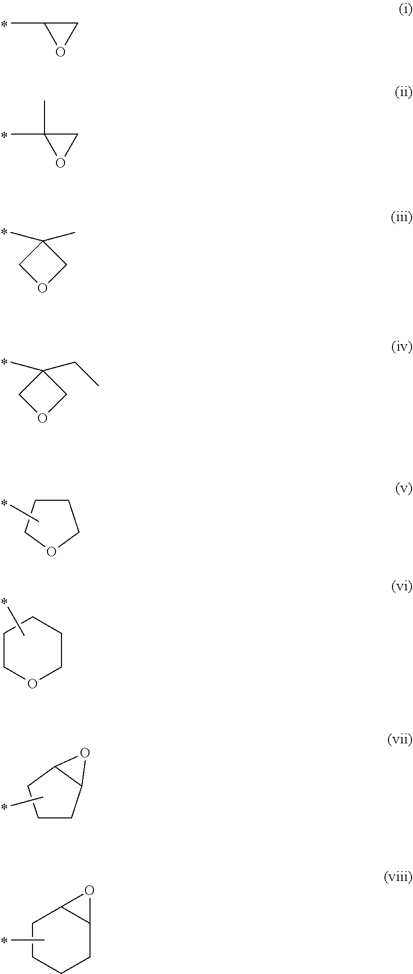

wherein the symbol “*” represents a linking bond that is to be bonded to R¹⁶.

According to the present invention, regarding R⁸ to R¹⁰, a hydrocarbon group is preferred in order to enhance desired effects.

The particular polymer chain may have a repeating unit other than the repeating units (1) and (2) (hereinafter, also referred to as another repeating unit). An example of such a repeating unit may be a repeating unit derived from a vinyl-based monomer having an anionic group. Examples of the anionic group include a carboxyl group, a sulfonic acid group, a phosphoric acid group, and a hydroxyl group exhibiting anionicity, and among these, a carboxyl group and a sulfonic acid group are preferred, while a carboxyl group is more preferred.

Suitable specific examples of the vinyl-based monomer having anionicity include vinyl-based monomers having an acidic group, such as (meth)acrylic acid, maleic acid, maleic anhydride, styrenesulfonic acid, 2-(meth)acrylamido-2-methylpropanesulfonic acid, allylsulfonic acid, vinylsulfonic acid, (meth)acrylsulfonic acid, sulfopropyl (meth)acrylate, mono[2-(meth)acryloyloxyethyl]succinate, ω-carboxypolycaprolactone mono(meth)acrylate, and an p-vinylbenzoic acid, p-hydroxystyrene, and p-hydroxy-α-methylstyrene, and salts thereof. These may be used singly, or two or more kinds thereof may be used in combination. Among these, (meth)acrylic acid, maleic acid, and maleic anhydride are preferred. In addition to those, examples of a monomer that constitutes the another repeating unit include cyclic maleimides in which N-position is substituted, such as N-phenylmaleimide and N-cyclohexylmaleimide; (meth)acrylic acid esters having a hydroxyl group, such as 2-hydroxyethyl (meth)acrylate, glycerol mono(meth)acrylate, and 4-hydroxyphenyl (meth)acrylate; and (meth)acrylamide-based monomers such as (meth)acrylamide and N-methylolacrylamide. The particular polymer chain may have one kind or two or more kinds of monomers corresponding to the other repeating unit.

The term “(meth)acrylate” according to the invention means “acrylate or methacrylate”.

The copolymerization proportion of the repeating unit (1) in the particular polymer chain is preferably 10% to 99% by mass, more preferably 15% to 95% by mass, even more preferably 20% to 90% by mass, and particularly preferably 50% to 85% by mass, with respect to all the repeating units. The copolymerization proportion of the repeating unit (2) is preferably 1% to 80% by mass, more preferably 5% to 75% by mass, even more preferably 10% to 70% by mass, and particularly preferably 15% to 50% by mass, with respect to all the repeating units. By copolymerizing various repeating units at such proportions, desired effects can be further enhanced. Furthermore, the mass ratio [(1)/(2)] of the copolymerization proportion of the repeating unit (1) and the copolymerization proportion of the repeating unit (2) is preferably 15/85 to 99/1, more preferably 20/80 to 95/5, and particularly preferably 30/70 to 90/10.

The copolymerization proportion or the copolymerization ratio can be measured by, for example, thermal decomposition gas chromatography analysis. For example, in Synthesis Example 1 that will be described below, peaks originating from DAMA, nBMA, MMA, and EHMA can be identified and quantitatively determined from the peak fragments of various chromatograms, and the copolymerization ratio can be calculated. An example of the measurement conditions will be described below. The copolymerization ratio can also be measured by NMR.

<Identification of Composition Ratio of Polymer>

Apparatus: Thermal decomposition gas chromatogram mass analyzer (thermal decomposition unit: pyrofoil sampler JPS-350 manufactured by Japan Analytical Industry Co., Ltd., gas chromatograph unit: Agilent Technologies 7890A GC System, mass analyzer unit: Agilent Technologies 5975 inert XL Mass Selective detector)

Column: BPX-5

Temperature: Thermal decomposition temperature 590° C. x 5 seconds, Column injection port 280° C., column temperature (initiation temperature set at 50° C., and heating up to 350° C. at a rate of 10° C. per minute)

Flow rate: He 1.0 mL/min

Ionization method: Electroionization method (EI method)

Detection unit: MS quadrupole, Aux-2

The particular polymer chain may have one kind or two or more kinds of monomers corresponding to the repeating unit (1), and may have one kind or two or more kinds of monomers corresponding to the repeating unit (2); however, it is preferable that in the particular polymer chain, only a repeating unit (1) in which Z represents a group forming an organic ammonium salt is included as the repeating unit (1), or a repeating unit (1) in which Z represents a group forming an organic ammonium salt and a repeating unit (1) in which Z represents —NR⁵R⁶ are both included.

Furthermore, it is preferable, from the viewpoint of enhancing desired effects, that the repeating unit (1) includes a repeating unit in which Z represents a group forming an organic ammonium salt, preferably at a proportion of 30 mol % or greater, more preferably 40 mol % or greater, even more preferably 50 mol % or greater, and particularly preferably 60 mol % or greater (meanwhile, the upper limit of this content is not particularly limited, and for example, the upper limit is 100 mol %). In a case in which a repeating unit in which Z represents a group forming an organic ammonium salt, and a repeating unit in which Z represents —NR⁵R⁶ are both included, the copolymerization ratio (molar ratio) of the repeating unit in which Z represents a group forming an organic ammonium salt and the repeating unit in which Z represents —NR⁵R⁶ is preferably 20/80 to 99/1, more preferably 30/70 to 98/2, and particularly preferably 40/60 to 95/5.

In a case in which the particular polymer chain has the repeating unit (1) and the repeating unit (2), the particular polymer chain may be any of a block copolymer and a random copolymer, and there are no particular limitations. However, in order to enhance desired effects, it is preferable that the particular polymer chain is a random copolymer.

The block copolymer may be a block copolymer including a block A that does not have the repeating unit (2) but has the repeating unit (1); and a block B that does not have the repeating unit (1) but has the repeating unit (2). The block copolymer may be an A-B type block copolymer. In the block A, two or more kinds of the repeating unit (1) may be included in one block A, and in that case, the respective repeating units may be included in the form of any of random copolymerization or block copolymerization in that block A. Similarly, in the block B, two or more kinds of the repeating unit (2) may be included in one block B, and in that case, the respective repeating units may be included in the form of any of random copolymerization or block copolymerization in that block B.

Regarding the molecular weight of the particular polymer chain, the weight average molecular weight Mw measured by gel permeation chromatography (GPC, mobile phase: tetrahydrofuran) and calculated relative to polystyrene standards is preferably 3,000 or less, more preferably 300 to 3,000, and even more preferably 500 to 2,500. Furthermore, the ratio (Mw/Mn) between Mw of the particular polymer chain and the number average molecular weight Mn measured by GPC (mobile phase: tetrahydrofuran) and calculated relative to polystyrene standards, is preferably 1.0 to 1.8, more preferably 1.0 to 1.7, and particularly preferably 1.1 to 1.5. By adopting such a form into the particular polymer chain, desired effects can be enhanced.

In regard to the particular polymer chain, it is preferable that an end of the polymer chain is bonded to a particular partial structure, and particularly, it is preferable that an end of the particular polymer chain is bonded to an N atom derived from a particular functional group in the particular partial structure. Furthermore, it is preferable that the particular polymer chain has a divalent group formed by ring-opening of a cyclic ether group, and it is more preferable that due to higher reactivity, the particular polymer chain has a divalent group formed by ring-opening of a cyclic ether group, at an end of the polymer chain. Furthermore, it is preferable for the particular polymer that the divalent group formed by ring-opening of a cyclic ether group is bonded to a particular partial structure, and particularly, it is preferable that the divalent group formed by a cyclic ether group, is bonded to an N atom derived from a particular functional group in a particular partial structure.

The divalent group formed by ring-opening of a cyclic ether group is preferably a divalent group formed by ring-opening of a cyclic ether group having 3 to 7 carbon atoms that constitute a ring; more preferably a divalent group formed by ring-opening of a cyclic ether group represented by any one of Formulae (i-2) to (viii-2); and particularly preferably a divalent group formed by ring-opening of a cyclic ether group represented by Formula (i-2) (ring-opened epoxy group). The divalent group formed by ring-opening of a cyclic ether group represented by any one of Formulae (i-2) to (iv-2) is specifically represented by any one of the following Formulae (i-3) to (iv-3).

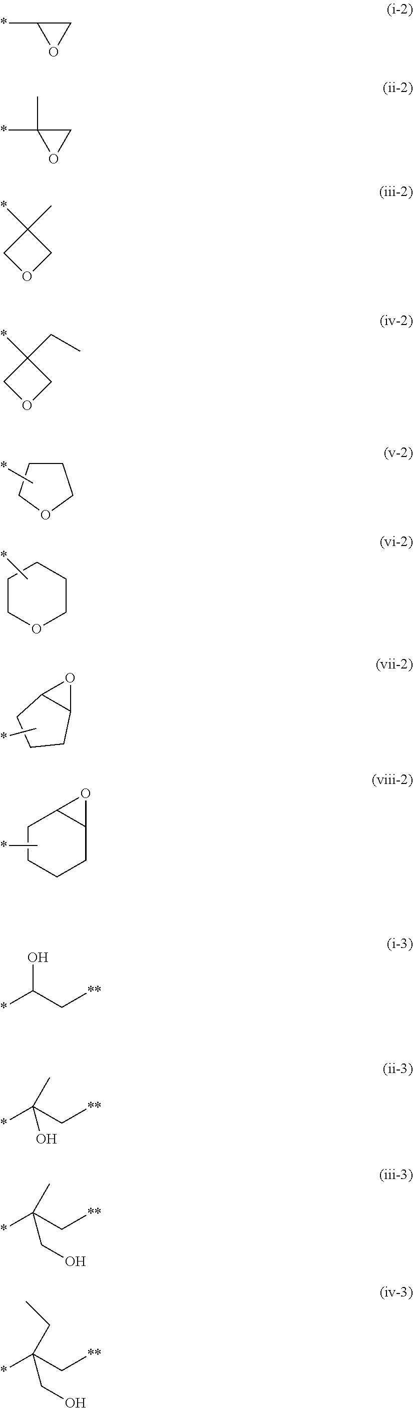

wherein the symbol “*” represents a linking bond that is to be bonded to a repeating unit (1) (in a case in which the particular polymer chain has a repeating unit (1) and a repeating unit (2), the repeating unit (1) or (2)); and the symbol “**” represents a linking bond that is to be bonded to an N atom derived from a particular functional group in a particular partial structure.

A repeating unit (1) (in a case in which the particular polymer chain has a repeating unit (1) and a repeating unit (2), the repeating unit (1) or (2)) and a divalent group formed by ring-opening of a cyclic ether group may be linked via a divalent linking group.

The divalent linking group is preferably a methylene group or an alkylene group having 2 to 12 carbon atoms. The alkylene group may be a linear group or a branched group. Specific examples of the divalent linking group include a methylene group, an ethylene group, an ethane-1,1-diyl group, a trimethylene group, a propane-1,1-diyl group, a propane-1,2-diyl group, a propane-2,2-diyl group, a tetramethylene group, a butane-1,2-diyl group, a butane-1,3-diyl group, a pentamethylene group, and a hexamethylene group.

The content of the particular polymer chain is preferably 40% to 99% by mass, more preferably 45% to 97% by mass, and particularly preferably 50% to 95% by mass, with respect to the total amount of the particular polymer, in order to enable further suppression of metal corrosion.

The content of the particular polymer chain can be measured by, for example, thermal decomposition gas chromatography. For example, in synthesis Example 1 that will be described below, peaks corresponding to a particular polymer and a particular polymer chain are identified and quantitatively determined from peak fragments of various chromatograms, and the content of the particular polymer chain can be calculated. An example of the measurement conditions will be described below. The content of the particular polymer chain can also be measured by NMR.

<Identification of Composition Ratio of Polymer>

Apparatus: Thermal decomposition gas chromatogram mass analyzer (thermal decomposition unit: pyrofoil sampler JPS-350 manufactured by Japan Analytical Industry Co., Ltd., gas chromatograph unit: Agilent Technologies 7890A GC System, mass analyzer unit: Agilent Technologies 5975 inert XL Mass Selective detector)

Column: BPX-5

Temperature: Thermal decomposition temperature 590° C. x 5 seconds, Column injection port 280° C., column temperature (initiation temperature set at 50° C., and heating up to 350° C. at a rate of 10° C. per minute)

Flow rate: He 1.0 mL/min

Ionization method: Electroionization method (EI method)

Detection unit: MS quadrupole, Aux-2

(Particular Partial Structure)

It is preferable that the particular polymer has a particular partial structure in addition to the particular polymer chain, in order to enhance desired effects.

The particular partial structure is a partial structure derived from a compound containing a particular functional group (group represented by —NH—). However, the particular partial structure is a concept that does not include the particular polymer chain. It is preferable that the particular partial structure is a residue by removing a part of or all of hydrogen atoms derived from the group represented by —NH—, from the compound containing a group represented by —NH—.

The compound containing a particular functional group is preferably a compound containing at least one selected from the group consisting of a primary amino group, a secondary amino group, a carbamoyl group (—C(═O)—NH₂), and an amide group (—C(═O)—NH—) as a particular functional group-containing group, in order to enable further suppression of corrosion. A compound containing at least one selected from the group consisting of a primary amino group, a secondary amino group, and a carbamoyl group is more preferred, and a compound containing at least one selected from the group consisting of a primary amino group and a secondary amino group is particularly preferred. Furthermore, the compound containing a particular functional group may be a compound containing one particular functional group or may be a compound containing a plurality of particular functional groups. However, a compound containing a plurality of particular functional groups is preferred.

The particular partial structure may be a structure derived from a low molecular weight (non-polymer form) compound or may be a high molecular weight (polymer form) compound; however, in order to enable further suppression of corrosion, the particular partial structure is preferably a structure derived from a high molecular weight (polymer form) amine compound, and among amine compounds, a structure derived from a multibranched type polymer is particularly preferred. When an amine compound is a multibranched type polymer, the particular polymer becomes a multibranched type star-shaped polymer having the particular partial structure as a core part and the particular polymer chain as an arm part. The weight average molecular weight of the amine compound in the form of a polymer is preferably 100 or more, and more preferably 150 or more, and the weight average molecular weight is preferably 3,000 or less, more preferably 2,500 or less, even more preferably 2,000 or less, and particularly preferably 1,500 or less.

Furthermore, in a case in which the compound containing a particularly functional group is a compound containing at least one selected from the group consisting of a primary amino group and a secondary amino group, some or all of amino groups derived from a compound containing a particular functional group in the particular partial structure may have been converted to an organic ammonium salt.

Examples of the compound containing a particular functional group include a polyaziridine-based polymer; polyaziridine-based polymer modification products such as an alkyl isocyanate modification product and an alkylene oxide modification product of a polyaziridine-based polymer; a diamine-based compound such as an aromatic diamine-based compound; a biguanide-based compound (may be a low molecular weight compound (non-polymer) or a high molecular weight compound (polymer)); an amino acid; an amino acid derivative; a peptide; an amino sugar; a polyamino sugar; and other antibacterial drugs. The particular polymer may have one kind of particular partial structures derived from these compounds, or may have two or more kinds thereof.

Among these, the compound containing a particular functional group is preferably a polyaziridine-based polymer, a diamine-based compound, a biguanide-based low molecular weight compound, an amino acid, or an amino acid derivative. In order to enable further suppression of corrosion, a polyaziridine-based polymer or a biguanide-based low molecular weight compound is more preferred, and a polyaziridine-based polymer is particularly preferred. The diamine-based compound is preferably an aromatic diamine-based compound. As described above, the weight average molecular weight of the polyaziridine-based polymer is preferably 100 or more, more preferably 150 or more, and the weight average molecular weight is preferably 3,000 or less, more preferably 2,500 or less, even more preferably 2,000 or less, and particularly preferably 1,500 or less. As described above, in a case in which the compound containing a particular functional group is a polyaziridine-based polymer, the particular polymer becomes a multibranched star-shaped polymer having the particular partial structure as a core part and the particular polymer chain as an arm part.

The polyaziridine-based polymer may be a polymer having a repeating unit represented by the following Formula (11).

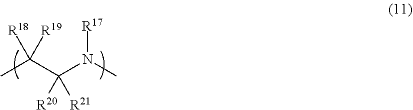

wherein

R¹⁷ represents hydrogen atom or a linking bond to be bonded to another repeating unit (11); and

R¹⁸ to R²¹ each independently represent a hydrogen atom, or a substituted or unsubstituted hydrocarbon group;

provided that in a case in which R¹⁸ and R¹⁹ together form a hydrocarbon group, R¹⁸ and R¹⁹ may be bonded together and form a ring, in a case in which R¹⁸ and R²⁰ together form a hydrocarbon group, R¹⁸ and R²⁰ may be bonded together and form a ring, and in a case in which R²⁰ and R²¹ together form a hydrocarbon group, R²⁰ and R²¹ may be bonded together and form a ring.

In a case in which R¹⁷ is a linking bond to be bonded to another repeating unit (11), Formula (11) is specifically represented by the following Formula (11-2). It is preferable that the polyaziridine-based polymer has both a repeating unit in which R¹⁷ represents a hydrogen atom, and a trivalent repeating unit represented by Formula (11-2).

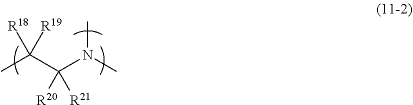

wherein R¹⁸ to R²¹ have the same meanings as R¹⁸ to R²¹ in Formula (11), respectively.

The hydrocarbon group represented by R¹⁸ to R²¹ is a concept including an aliphatic hydrocarbon group, an alicyclic hydrocarbon group, and an aromatic hydrocarbon group, similarly to the case of R² to R⁶. The hydrocarbon group may be in any one of a linear form, a branched form, and a cyclic form, and may be a saturated hydrocarbon group or an unsaturated hydrocarbon group. The hydrocarbon group may have an unsaturated bond at any of a terminal site or a non-terminal site. The hydrocarbon group represented by R¹⁸ to R²¹ is preferably an aliphatic hydrocarbon group, and preferably an alkyl group having 1 to 20 carbon atoms (preferably 1 to 12 carbon atoms, and more preferably 1 to 4 carbon atoms). Specific examples include a methyl group, an ethyl group, an n-propyl group, an isopropyl group, an n-butyl group, an isobutyl group, a sec-butyl group, and a tert-butyl group.

Examples of a ring that may be formed by R¹⁸ and R¹⁹, by R¹⁸ and R²⁰, or by R²⁰ and R²¹ include cycloalkane rings having 3 to 10 carbon atoms such as a cyclohexane ring, a methylcyclohexane ring, a cycloheptane ring, and a cyclooctane ring.

Examples of a substituent for R¹⁸ to R²¹ include an alkyl group having 1 to 6 carbon atoms, and a halogen atom.

Specific examples of the polyaziridine-based polymer include, for example, polyethyleneimine, polypropyleneimine poly(2,2-dimethylaziridine), poly(2,3-dimethylaziridine), poly(2,2,3,3-tetramethylaziridine), poly(2-ethylaziridine), poly(2-hexylaziridine), poly(7-azabicyclo[4.1.0]hexane), poly(1-azaspiro[2.5]octane), poly(1-methyl-7-azabicyclo[4.1.0]hetpane), and poly(3-methyl-7-azabicyclo[4.1.0]heptane). Among them, polyethyleneimine and polypropyleneimine are preferred, and polyethyleneimine is particularly preferred.

The diamine-based compound may be a compound represented by the following Formula (12) or (13).

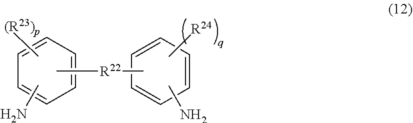

wherein

R²² represents a single bond, an ether bond, an amide bond, an ester bond, a thio group, or a divalent organic group;

R²³ and R²⁴ each independently represent a substituted or unsubstituted hydrocarbon group;

p and q each independently represent an integer from 0 to 4,

provided that R²² represents a divalent organic group, and when at least any one of p and q represents an integer from 0 to 3, R²² may form a condensed ring with an adjacent phenylene group.

H₂N—R²⁵—NH₂ (13)

wherein R²⁵ represents a substituted or unsubstituted divalent aromatic hydrocarbon group, or a substituted or unsubstituted divalent nitrogen-containing heterocyclic group.

In Formula (12), R²² represents a single bond, an ether bond, an amide bond, an ester bond, a thio group, or a divalent organic group. Among these, a single bond, an ether bond, a thio group, and a divalent organic group are preferred, and a divalent organic group is more preferred.

The divalent organic group is more preferably a substituted or unsubstituted divalent hydrocarbon group, or a group in which some of the carbon atoms of the substituted or unsubstituted divalent hydrocarbon group have been substituted by one or more selected from the group consisting of an ether bond, an amide bond, an ester bond, and a thio group; even more preferably a substituted or unsubstituted divalent hydrocarbon group, or a group in which some of the carbon atoms of the substituted or unsubstituted divalent hydrocarbon group have been substituted by one or more selected from the group consisting of an ether bond and an ester bond; and particularly preferably a group in which some of the carbon atoms of a substituted or unsubstituted divalent hydrocarbon group have been substituted by an ester bond. The number of carbon atoms of the divalent organic group is preferably 1 to 50, more preferably 2 to 40, even more preferably 3 to 30, and particularly preferably 5 to 20. In regard to a group in which some of the carbon atoms of a substituted or unsubstituted divalent hydrocarbon group have been substituted by one or more selected from the group consisting of an ether bond, an amide bond, an ester bond, and a thio group, there may be one ether bond, amide bond, ester bond, or thio group, or there may be two or more thereof.

The “divalent hydrocarbon group” for R²² may be any one of a divalent aliphatic hydrocarbon group, a divalent alicyclic hydrocarbon group, and a divalent aromatic hydrocarbon group. Furthermore, a divalent group formed by these hydrocarbon groups linked together may also be used.

The number of carbon atoms of the divalent aliphatic hydrocarbon group is preferably 1 to 50, more preferably 2 to 40, even more preferably 3 to 30, and particularly preferably 5 to 20. The divalent aliphatic hydrocarbon group may be a linear group or a branched group. The divalent aliphatic hydrocarbon group may have an unsaturated bond in the molecule; however, the divalent aliphatic hydrocarbon group is preferably an alkanediyl group. Specific examples of an alkanediyl group include a methane-1,1-diyl group, an ethane-1,1-diyl group, an ethane-1,2-diyl group, a propane-1,1-diyl group, a propane-1,2-diyl group, a propane-1,3-diyl group, a propane-2,2-diyl group, a butane-1,1-diyl group, a butane-1,2-diyl group, a butane-1,3-diyl group, a butane-1,4-diyl group, a pentane-1,1-diyl group, a bentane-1,2-diyl group, a pentane-1,3-diyl group, a pentane-1,4-diyl group, a pentane-1,5-diyl group, a hexane-1,1-diyl group, a hexane-1,2-diyl group, a hexane-1,3-diyl group, a hexane-1,4-diyl group, a hexane-1,5-diyl group, a hexane-1,6-diyl group, a heptane-1,7-diyl group, an octane-1,8-diyl group, a nonane-1,9-diyl group, and a decane-1,10-diyl group.

The number of carbon atoms of the divalent alicyclic hydrocarbon group is preferably 3 to 20, more preferably 3 to 16, even more preferably 3 to 12, and particularly preferably 3 to 8. Specific examples include cycloalkylene groups such as a cyclopropylene group, a cyclobutylene group, a cyclopentylene group, and a cyclohexylene group.

The number of carbon atoms of the divalent aromatic hydrocarbon group is preferably 6 to 18, and more preferably 6 to 12. Specific examples include a phenylene group, a naphthylene group, a phenanthrene group, an anthrylene group, and a fluorenylene group (fluorene ring-derived divalent group).

The bonding site of the divalent alicyclic hydrocarbon group and the bonding site of the divalent aromatic hydrocarbon group may be at any carbon atom on the ring.

Examples of a substituent for R²² include an alkyl group having 1 to 6 carbon atoms, and a halogen atom.

In Formula (12), R²³ and R²⁴ each independently represent a substituted or unsubstituted hydrocarbon group. Similarly to the case of R² to R⁶ described above, the hydrocarbon group represented by R²³ and R²⁴ is a concept including an aliphatic hydrocarbon group, an alicyclic hydrocarbon group, and an aromatic hydrocarbon group, and the hydrocarbon group may be any of a linear form, a branched form, and a cyclic form. Furthermore, the hydrocarbon group may be a saturated hydrocarbon group or may be an unsaturated hydrocarbon group, and may have an unsaturated bond at any of a terminal site and a non-terminal site. The hydrocarbon group represented by R²³ and R²⁴ is preferably an aliphatic hydrocarbon group, and preferably an alkyl group having 1 to 20 carbon atoms (preferably 1 to 12 carbon atoms, and more preferably 1 to 4 carbon atoms). Specific examples include a methyl group, an ethyl group, an n-propyl group, an isopropyl group, an n-butyl group, an isobutyl group, a sec-butyl group, and a tert-butyl group. Examples of a substituent for R²³ and R²⁴ include a halogen atom.

In Formula (12), p and q each independently represent an integer from 0 to 4. p or q is preferably 0 or 1, and more preferably 0. In a case in which p represents an integer from 2 to 4, p units of R²³ may be identical with or different from each other, and in a case in which q represents an integer from 2 to 4, q units of R²⁴ may be identical with or different from each other.

In Formula (13), R²⁵ represents a substituted or unsubstituted divalent aromatic hydrocarbon group, or a substituted or unsubstituted divalent nitrogen-containing heterocyclic group.

The number of carbon atoms of the divalent aromatic hydrocarbon group is preferably 6 to 18, and more preferably 6 to 12. Specific examples include a phenylene group, a naphthylene group, a phenanthrene group, an anthrylene group, and a fluorenylene group (fluorene ring-derived divalent group).

The number of carbon atoms of the divalent nitrogen-containing heterocyclic group is preferably 4 to 18, and more preferably 4 to 10. Specific examples include a pyridinylene group (pyridine ring-derived divalent group), a pyrimidinylene group (pyrimidine ring-derived divalent group), an acridinylene group (acridine ring-derived divalent group), and a carbazole ring-derived divalent group.

The bonding site of the divalent aromatic hydrocarbon group and the bonding site of the divalent nitrogen-containing heterocyclic group may be at any carbon atom on the ring.

Examples of a substituent for R²⁵ include an alkyl group having 1 to 6 carbon atoms, a halogen atom, and a carboxy group.

Specific examples of the diamine-based compound include, for example, bis(4-aminophenylethyl) adipate, 4,4′-diaminodiphenylmethane, 4,4′-diaminodiphenyl sulfide, 2,2′-dimethyl-4,4′-diaminobiphenyl, 2,2′-bis(trifluoromethyl)-4,4′-diaminobiphenyl, 4,4′-diaminodiphenyl ether, 2,2-bis[4-(4-aminophenoxy)phenyl]propane, 9,9-bis(4-aminophenyl)fluorene, 2,2-bis[4-(4-aminophenoxy)phenyl]hexanefluoropropane, 2,2-bis(4-aminophenyl)hexafluoropropane, 4,4′-(p-phenylenediisopropylidene)bisaniline, 4,4′-(m-phenylenediisopropylidene)bisaniline, 1,4-bis(4-aminophenoxy)benzene, 4,4′-bis(4-aminophenoxy)biphenyl, 1-(4-aminophenyl)-2,3-dihydro-1,3,3-trimethyl-1H-indene-5-amine, 1-(4-aminophenyl)-2,3-dihydro-1,3,3-trimethyl-1H-indene-6-amine, p-phenylenediamine, 1,5-diaminonaphthalene, 2,7-diaminofluorene, 3,5-diaminobenzoic acid, 2,6-diaminopyridine, 3,4-diaminopyridine, 2,4-diaminopyrimidine, 3,6-diaminoacridine, and 3,6-diaminocarbazole.

The biguanide-based compound is desirably a compound having at least one biguanide skeleton in the molecule, and the biguanide-based compound may be a low molecular weight compound containing one biguanide skeleton, or may be a compound having a plurality of repeating units each containing a biguanide skeleton, such as polyhexamethylene biguanide. Among them, in order to enhance desired effects, a low molecular weight compound containing one biguanide skeleton is preferred. The low molecular weight compound containing one biguanide skeleton may be a compound represented by the following Formula (14).

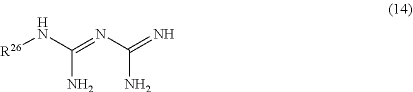

wherein R²⁶ represents an organic group.

In Formula (14), the organic group represented by R²⁶ is preferably a substituted or unsubstituted hydrocarbon group.

Similarly to the case of R² to R⁶, the hydrocarbon group represented by R²⁶ is a concept encompassing an aliphatic hydrocarbon group, an alicyclic hydrocarbon group, and an aromatic hydrocarbon group, and the hydrocarbon group may be in any of a linear form, a branched form, and a cyclic form. Furthermore, the hydrocarbon group may be a saturated hydrocarbon group or an unsaturated hydrocarbon group, and may have an unsaturated bond at any one of a terminal site and a non-terminal site.

The aliphatic hydrocarbon group is preferably an alkyl group having 1 to 20 carbon atoms (preferably 1 to 12 carbon atoms, more preferably 1 to 6 carbon atoms, and particularly preferably 1 to 4 carbon atoms). Specific examples include a methyl group, an ethyl group, an n-propyl group, an isopropyl group, an n-butyl group, an isobutyl group, a sec-butyl group, and a tert-butyl group. Furthermore, the alicyclic hydrocarbon group is preferably an alicyclic hydrocarbon group having 3 to 20 carbon atoms (preferably 3 to 12 carbon atoms), and more preferably a cycloalkyl group having 3 to 20 carbon atoms (preferably 3 to 12 carbon atoms). Specific examples include a cyclopropyl group, a cyclobutyl group, a cyclopentyl group, and a cyclohexyl group. Furthermore, the aromatic hydrocarbon group is preferably an aromatic hydrocarbon group having 6 to 20 carbon atoms (preferably 6 to 10 carbon atoms), and more preferably an aryl group having 6 to 20 carbon atoms (preferably 6 to 10 carbon atoms), or an aralkyl group having 7 to 20 carbon atoms (preferably 7 to 16 carbon atoms). The aryl group refers to a monocyclic to tricyclic aromatic hydrocarbon group, and examples include a phenyl group, a naphthyl group, a biphenyl group, and an anthranyl group. Specific examples of the aralkyl group include a benzyl group, a phenethyl group, an α-methylbenzyl group, and a 2-phenylpropan-2-yl group.

Among these, the hydrocarbon group for R²⁶ is preferably an alkyl group having 1 to 12 carbon atoms (more preferably 1 to 6 carbon atoms, and particularly preferably 1 to 4 carbon atoms), or an aryl group having 6 to 10 carbon atoms, and particularly preferably an aryl group having 6 to 10 carbon atoms.

Examples of a substituent for R²⁶ include an alkyl group having 1 to 6 carbon atoms (for example, a methyl group, an ethyl group, an n-propyl group, an isopropyl group, an n-butyl group, an isobutyl group, a sec-butyl group, or a tert-butyl group), a halogen atom, and an alkoxy group having 1 to 6 carbon atoms.

Suitable specific examples of the biguanide-based compound include, for example, ethyl biguanide, 1-butyl biguanide, 1-octadecyl biguanide, phenyl biguanide, l-o-tolyl biguanide, l-p-tolyl biguanide, 1-(2-phenylethyl) biguanide, 1-(2,3-xylyl) biguanide, and 1-(4-methoxyphenyl) biguanide.

Examples of the amino acid and amino acid derivative include known amino acids and amino acid derivatives. Examples of the peptide and antibacterial drug include known oligopeptides, polypeptides, peptide structures, and antibiotic substances containing a primary amino group or a secondary amino group.

The amino acid derivative is preferably an N-acylamino acid, and more preferably an N-alkanoylamino acid. The alkanoyl group for the N-alkanoylamino acid is preferably an alkanoyl group having 2 to 10 carbon atoms, and more preferably an alkanoyl group having 2 to 6 carbon atoms. Specific examples of the alkanoyl group include an acetyl group and a propionyl group. The amino acid derivative is particularly preferably N-acetylamino acid.

Specific examples of the amino acid, amino acid derivative, peptide, and antibacterial drugs include lysine, glycine, alanine, glutamine, glutamic acid, N-acetyl-L-glutamine, N-acetyl-L-glutamic acid, polylysine, glycylglycine, glycylsarcosine, glutathione, L-alanyl-L-glutamine, daptomycin, vancomycin, colistin, ampicillin, cefditoren pivoxil, sephalosporin C, aztreonam, tigemonam, streptomycin, gentamycin, arbekacin, minocycline, tosufloxacin, trimethoprim, sulfamethoxazole, acyclovir, valacyclovir, lamivudine, and nystatin.

Furthermore, examples of the amino sugar and the polyamino sugar include glucosamine, galactosamine, mannosamine, hexosamine, and chitosan.

The content of the particular partial structure is preferably 1% to 60% by mass, more preferably 3% to 55% by mass, and particularly preferably 5% to 50% by mass, with respect to the total amount of the particular polymer, in order to enable further suppression of metal corrosion.

Furthermore, the mass proportions of the contents of the particular polymer chain and the particular partial structure are preferably 40/60 to 99/1, more preferably 45/55 to 97/3, and particularly preferably 50/50 to 95/5, in order to enable further suppression of metal corrosion.

The content of the particular partial structure can be measured by, for example, thermal decomposition gas chromatography.

Next, a method for producing the particular polymer will be explained.

The particular polymer can be produced by appropriately combining known methods. For example, a monomer that provides the repeating unit (1) and, if necessary, another monomer may be (co)polymerized. In the case of producing a particular polymer having a particular partial structure, it is preferable that the particular polymer is obtained by a method including the following steps 1 and 2.

(Step 1) A step of bringing a polymer having a repeating unit (1) (preferably a copolymer having a repeating unit (1) and a repeating unit (2)) into contact with a compound having a cyclic ether group, and thereby introducing a cyclic ether group into the polymer; and

(Step 2) A step of bringing a cyclic ether group-containing polymer obtained in step 1 into contact with a compound containing a particular functional group, and thereby allowing to react the cyclic ether group with the particular functional group.

(Step 1)

Step 1 is a process for bringing a polymer having the repeating unit (1) into contact with a compound having a cyclic ether group and introducing a cyclic ether group into the polymer.

Regarding the polymer having the repeating unit (1), a commercially available product may be used, or a chemically synthesized polymer may be used; however, it is preferable to produce the polymer by subjecting monomers that provide the various repeating units to living polymerization. Regarding the living polymerization method, known methods such as living radical polymerization and living anionic polymerization can be employed.

Examples of a monomer that provides the repeating unit (1), in which Z in Formula (1) represents a group forming an organic ammonium salt or —NR⁵R⁶, include (meth)acrylic acid esters containing an ammonium salt type cationic functional group or an amino group, such as (meth)acryloylaminopropyltrimethylammonium chloride, (meth)acryloyloxyethyltrimethylammonium chloride (meth)acryloyloxyethyltriethylammonium chloride, (meth)acryloyloxyethyl (4-benzoylbenzyl)dimethylammonium bromide, (meth)acryloyloxyethyl benzyldimethylammonium chloride, (meth)acryloyloxyethyl benzyldiethylammonium chloride, dimethylaminoethyl (meth)acrylate, diethylaminoethyl (meth)acrylate, dimethylaminopropyl (meth)acrylate, and diethylaminopropyl (meth)acrylate; and (meth)acrylamides corresponding to these.

It is preferable that the repeating unit (1) in which Z represents a group forming an organic ammonium salt is obtained by reacting a monomer in which Z represents —NR⁵R⁶ (for example, dimethylaminoethyl (meth)acrylate), after copolymerization, after step 1, or after step 2, with a halogenated hydrocarbon compound such as benzyl chloride, and quaternarizing the amino group. Particularly, it is preferable to obtain the repeating unit (1) by quaternarizing the amino group after step 2.

Examples of the monomer that provides the repeating unit (1), in which Z in Formula (1) is a nitrogen-containing heterocyclic group, include Compound Group a represented by the following formulae (monomers 1 to 18), a compound represented by the following Formula (5), 4-vinylpyridine, and salts thereof. The monomers that provide the repeating unit (1) can be used singly or in combination of two or more kinds thereof.

[Compound Group α]

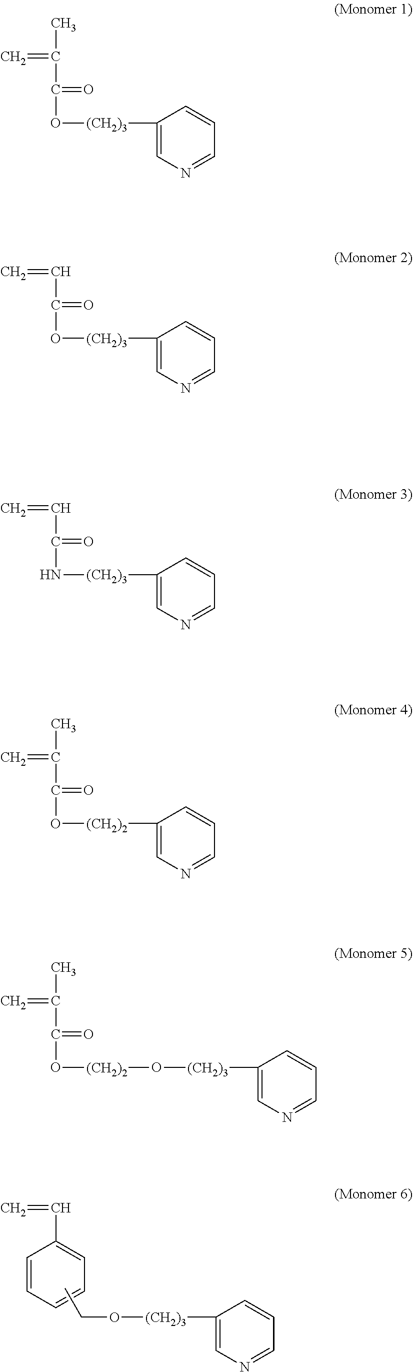

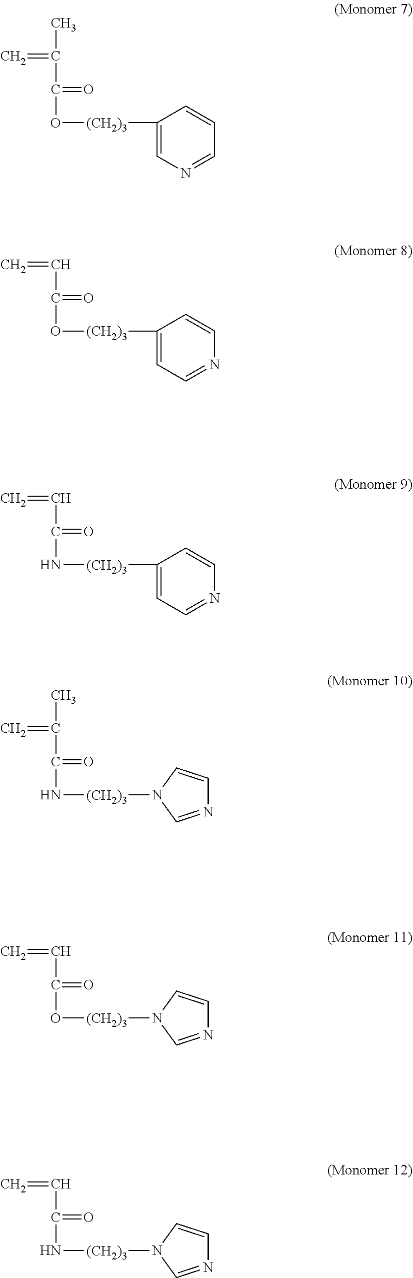

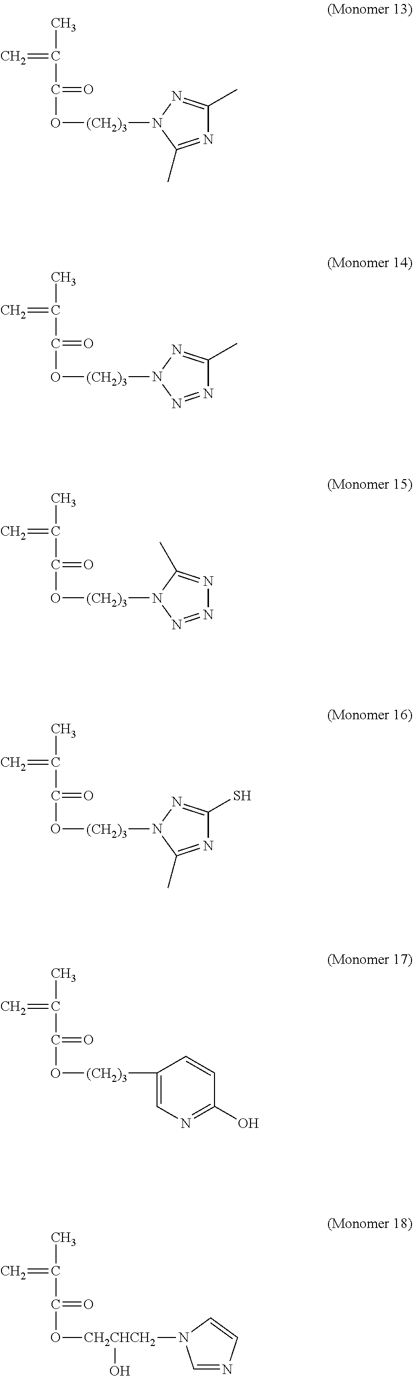

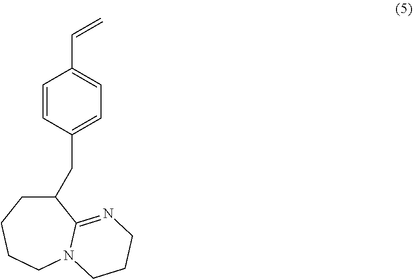 [SMILES: C=Cc1ccc(CC2CCCCN3CCCN=C23)cc1]

The monomer that provides the repeating unit (2) is a monomer that provides a repeating unit (2) in which A represents an aromatic hydrocarbon group, and examples thereof include styrene and α-methylstyrene. Furthermore, examples of the monomer that provides the repeating unit (2) in which R⁸ to R¹⁰ each represent a hydrocarbon group, include (meth)acrylic acid esters such as methyl (meth)acrylate, ethyl (meth)acrylate, propyl (meth)acrylate, isopropyl (meth)acrylate, butyl (meth)acrylate, isobutyl (meth)acrylate, t-butyl (meth)acrylate, 2-ethylhexyl (meth)acrylate, isodecyl (meth)acrylate, dodecyl (meth)acrylate, cyclohexyl (meth)acrylate, t-butylcyclohexyl (meth)acrylate, cyclohexenyl (meth)acrylate, tricyclo[5.2.1.0^{2,6}]decan-8-yl (meth)acrylate, dicyclopentenyl (meth)acrylate, isobornyl (meth)acrylate, adamantyl (meth)acrylate, decahydro-2-naphthyl (meth)acrylate, and pentacyclopentadecanyl (meth)acrylate; (meth)acrylamides corresponding to these; and vinyl ethers such as ethyl vinyl ether. Furthermore, examples of a monomer that provides the repeating unit (2) in which R⁸ to R¹⁰ each represent a group having a linear or cyclic ether structure, include (meth)acrylic acid esters having a linear or cyclic ether structure, such as polyethylene glycol (n=2 to 10) methyl ether (meth)acrylate, polypropylene glycol (n=2 to 10) methyl ether (meth)acrylate, polyethylene glycol (n=2 to 10) ethyl ether (meth)acrylate, polypropylene glycol (n=2 to 10) ethyl ether (meth)acrylate, polyethylene glycol (n=2 to 10) mono(meth)acrylate, polypropylene glycol (n=2 to 10) mono(meth)acrylate, ethylene oxide-modified (meth)acrylate of para-cumylphenol, glycidyl (meth)acrylate, 3,4-epoxycyclohexylmethyl (meth)acrylate, 3-[(meth)acryloyloxymethyl]oxetane, 3-[(meth)acryloyloxymethyl]-3-ethyloxetane, and tetrahydrofurfuryl (meth)acrylate; (meth)acrylamides corresponding to these; vinyl ethers such as 3-(vinyloxymethyl)-3-ethyloxetane. These can be used singly or in combination of two or more kinds thereof.

Furthermore, examples of a monomer that provides a repeating unit other than the repeating unit (1) and the repeating unit (2) include vinylic monomers having an acidic group, such as (meth)acrylic acid, maleic acid, maleic anhydride, styrenesulfonic acid, 2-(meth)acrylamido-2-methylpropanesulfonic acid, allylsulfonic acid, vinylsulfonic acid, (meth)acrylsulfonic acid, sulfopropyl (meth)acrylate, mono[2-(meth)acryloyloxyethyl]succinate, ω-carboxypolycaprolactone mono(meth)acrylate, p-vinylbenzoic acid, p-hydroxystyrene, and p-hydroxy-α-methylstyrene; N-substituted maleimides such as N-phenylmaleimide and N-cyclohexylmaleimide; (meth)acrylic acid esters having a hydroxyl group, such as 2-hydroxyethyl (meth)acrylate, glycerol mono(meth)acrylate, and 4-hydroxyphenyl (meth)acrylate; and (meth)acrylamide-based monomers such as (meth)acrylamide and N-methylolacrylamide. These can be used singly or in combination of two or more kinds thereof.

The compound having a cyclic ether group is desirably a compound capable of introducing a cyclic ether group into a polymer having the repeating unit (1), and examples include epihalohydrins such as epichlorohydrin, epibromohydrin, epifluorohydrin, and epiiodohydrin. These can be used singly or in combination of two or more kinds.

The amount of use of the compound having a cyclic ether group is usually about 0.05 to 0.2 molar equivalents with respect to the polymer having the repeating unit (1).

The reaction time for step 1 is usually 0.5 to 2.5 hours, and the reaction temperature is usually −78° C. to 20° C.

(Step 2)

Step 2 is a process of bringing the cyclic ether group-containing polymer obtained in step 1 into contact with a compound containing a particular functional group, and reacting the cyclic ether group with the particular functional group.

Regarding the compound containing a particular functional group, a compound that provides the particular partial structure may be used.

The amount of use of the compound containing a particular functional group is usually about 0.7 to 1.3 molar equivalents with respect to the cyclic ether group-containing polymer.

Step 2 may be carried out in the presence of an organic phosphorus compound. The organic phosphorus compound is preferably triphenylphosphine or a derivative thereof, such as triphenylphosposphine, tris(3-methylphenyl)phosphine, tris(4-methylphenyl)phosphine, tris(3,5-dimethylphenyl)phosphine, diphenyl(pentafluorophenyl)phosphine, tris(pentafluorophenyl)phosphine, tris(4-chlorophenyl)phosphine, or tris[4-(methylthio)phenyl]phosphine. These can be used singly or in combination of two or more kinds thereof.

The reaction time of step 2 is usually 10 to 40 hours, and the reaction temperature is usually 40° C. to 80° C.

The respective steps described above may be carried out in the presence or absence of a solvent. Examples of the solvent include water; alcohols such as methanol, ethanol, propanol, isopropyl alcohol, n-butyl alcohol, isobutyl alcohol, sec-butyl alcohol, and t-butyl alcohol; ethylene glycol derivatives such as ethylene glycol, ethylene glycol monomethyl ether, ethylene glycol monoethyl ether, ethylene glycol monopropyl ether, ethylene glycol monobutyl ether, ethylene glycol monoethyl ether acetate, diethylene glycol monomethyl ether, diethylene glycol monoethyl ether, diethylene glycol dimethyl ether, and diethylene glycol diethyl ether; propylene glycol derivatives such as propylene glycol, propylene glycol monomethyl ether, propylene glycol monoethyl ether, propylene glycol monopropyl ether, propylene glycol monobutyl ether, and propylene glycol monomethyl ether acetate; ketones such as acetone, methyl ethyl ketone, methyl isobutyl ketone, methyl amyl ketone, diisobutyl ketone, and cyclohexanone; esters such as ethyl acetate, butyl acetate, isobutyl acetate, ethyl lactate, and γ-butyllactone; amides such as N,N-dimethylformamide, N,N-dimethylacetamide, N-methylpyrrolidone, hexamethyl phosphoric acid triamide, 1,3-dimethyl-2-imidazoline, N,N′-dimethylpropyleneurea, tetramethylurea, and N-methylpyrrolidone; sulfoxides such as dimethyl sulfoxide; aromatic hydrocarbons such as toluene, xylene, and nitrobenzene; and ethers such as tetrahydrofuran, 1,3-dioxolane, diethyl ether, and morpholine. Among these, one kind thereof may be used alone, or two or more kinds thereof may be used in combination.

In regard to the respective steps, isolation of various reaction products may be carried out by appropriately combining conventional means such as filtration, washing, drying, recrystallization, reprecipitation, dialysis, centrifugation, extraction using various solvents, neutralization, and chromatography, as necessary.

From the viewpoint that metal corrosion can be further suppressed, and contamination can be effectively reduced or eliminated, the content of the component (A) is preferably 0.0001 to 0.5% by mass, more preferably 0.001% to 0.1% by mass, and particularly preferably 0.005% to 0.1% by mass, with respect to the total mass of the composition for treating a surface of semiconductor.

<Component (B)>

The composition for treating a surface of semiconductor of the present invention includes (B) a chelating agent having a molecular weight of 500 or less.

Here, according to the present specification, a chelating agent refers to a compound having a multidentate ligand that is bonded to a metal ion to form a chelate compound, the compound being a compound other than the component (A). The molecular weight of the chelating agent used for the present invention is 500 or less. Such a chelating agent may be used singly, or two or more kinds thereof may be used in combination.

The molecular weight of the chelating agent is preferably 60 to 480, and more preferably 60 to 300. Furthermore, a low molecular weight (non-polymer form) chelating agent is preferred. It is also preferable that the chelating agent has a coordinative ability for an ion formed from an element of semiconductor material.

The “chelating agent” such as described above is preferably an organic amine-based chelating agent, or an organic acid-based chelating agent having two or more carboxyl groups, since the performance of reducing or eliminating residue can be enhanced.

(Organic Acid-Based Chelating Agent Having Two or More Carboxy Groups)

Examples of the organic acid-based chelating agent include polycarboxylic acid-based chelating agents that do not have a hydroxyl group, such as oxalic acid, malonic acid, succinic acid, maleic acid, and salts thereof (alkali metal salts (for example, potassium salt) and ammonium salts); organic acid-based chelating agents each having two or more carboxyl groups and one or more hydroxyl groups, such as citric acid (molecular weight: 192), malic acid (molecular weight: 134), tartaric acid, and salts thereof (alkali metal salts (for example, potassium salt) and ammonium salt); and aminopolycarboxylic acid-based chelating agents such as ethylenediamine tetraacetate (molecular weight: 292), glycol ether diamine tetraacetate, and salts thereof (alkali metal salts (for example, potassium salt) and ammonium salts). The polycarboxylic acid-based chelating agent that does not have a hydroxyl group is preferably a dicarboxylic acid-based chelating agent that does not have a hydroxyl group. The aminopolycarboxylic acid-based chelating agent is preferably an aminopolyacetic acid-based chelating agent.

These organic acid-based chelating agents may be used singly, or two or more kinds thereof may be used in combination.

Among these organic acid-based chelating agents, in order to enhance the performance of reducing or eliminating residue, an organic acid-based chelating agent having two or more carboxyl groups and one or more hydroxyl groups, or an aminopolycarboxylic acid-based chelating agent is preferred, and an organic acid-based chelating agent having two or more carboxyl groups and one or more hydroxyl groups is more preferred.

(Organic Amine-Based Chelating Agent)

Examples of the organic amine-based chelating agent include alkanolamine-based chelating agents such as monoethanolamine (molecular weight: 61), diethanolamine, triethanolamine, N-methylethanolamine, N-methyl-N,N-diethanolamine, N,N-dimethylethanolamine, N,N-diethylethanolamine, N,N-dibutylethanolamine, N—(β-aminoethyl)ethanolamine, N-ethylethanolamine, monopropanolamine, dipropanolamine, tripropanolamine, monoisopropanolamine, diisopropanolamine, and triisopropanolamine; primary amine-based chelating agents such as methylamine, ethylamine, propylamine, butylamine, pentylamine, and 1,3-propanediamine; secondary amine-based chelating agents such as piperidine and piperazine; tertiary amine-based chelating agents such as trimethylamine and triethylamine; and amino acid-based chelating agents such as glycine, phenylalanine, alanine, asparagine, glutamine, tyrosine, lysine, proline, histidine (molecular weight: 155), arginine, leucine, isoleucine, methionine, serine, threonine, tryptophan, cysteine, and valine. Salts thereof are also acceptable. Examples of these salts include alkali metal salts such as potassium salts and sodium salts; ammonium salts; inorganic acid salts such as nitric acid salts, sulfuric acid salts, and hydrochloric acid salts; and organic acid salts such as acetic acid salts.

These organic amine-based chelating agents may be used singly, or two or more kinds thereof may be used in combination.

Among these organic amine-based chelating agents, an alkanolamine-based chelating agent and an amino acid-based chelating agent are preferred because the effect of eliminating residue on the surface of metal wiring is superior, and an alkanolamine-based chelating agent is more preferred.

The alkanolamine-based chelating agent is preferably a monoalkanolamine-based chelating agent, and particularly preferably monoethanolamine or monoisopropanolamine.

The content of the component (B) is preferably 0.001% to 0.5% by mass, more preferably 0.005% to 0.3% by mass, even more preferably 0.01% to 0.1% by mass, and particularly preferably 0.01% to 0.05% by mass, with respect to the total mass of the composition for treating a surface of semiconductor, since metal corrosion can be further suppressed, and contaminations (particularly, deposits on the surface of metal wiring) can be effectively reduced or eliminated.

The content mass ratio [(B)/(A)] of the component (A) and the component (B) in the composition for treating a surface of semiconductor is preferably 0.1 to 100, more preferably 0.5 to 30, even more preferably 1 to 15, still more preferably 1.5 to 7.5, and particularly preferably 1.5 to 3, since the desired effects of the present invention are enhanced.

<Optional Components>

The composition for treating a surface of semiconductor of the invention may include components other than the component (A) and the component (B) (hereinafter, also referred to as “other components”). Examples of these other components include a water-based medium, polishing particles (abrasive grains), a water-soluble (co)polymer or a salt thereof, an oxidizing agent, a reducing agent, a surfactant, and a pH adjusting agent. These may be used singly, or two or more kinds thereof may be used in combination.

Examples of the water-based medium include water and a mixed solution of water and an alcohol; however, water is preferred. Examples of water include ion-exchanged water, pure water, and ultrapure water.

The content of the water-based medium is preferably 70% by mass or more, more preferably 90% by mass or more, and particularly preferably 95% by mass or more, and preferably less than 100% by mass, and more preferably 99.9999% by mass or less, with respect to the total mass of the composition for treating a surface of semiconductor.

The polishing particles are preferably inorganic oxide particles or organic particles, and inorganic oxide particles are more preferred. In a case in which the composition for treating a surface of semiconductor includes polishing particles, the composition becomes adequate for a polishing treatment such as chemical mechanical polishing. Meanwhile, since the composition for treating a surface of semiconductor of the invention does not easily corrode metals and has excellent residue elimination performance when used for cleaning after chemical mechanical polishing, the composition for treating a surface of semiconductor is suitable even as a composition for semiconductor surface cleaning treatment of a type that does not contain polishing particles.

Examples of the inorganic oxide particles include inorganic particles of silica, ceria, alumina, zirconia, and titania. Among these silica and alumina are preferred, and silica is more preferred. Examples of the silica include colloidal silica and fumed silica; however, since the generation of scratches on the surface of a wiring metal film can be further suppressed, colloidal silica is particularly preferred.

The primary particle size (D1) of the polishing particles is preferably 10 to 200 nm. The primary particle size (D1) can be measured by, for example, an observation method or a BET specific surface area method.

In regard to the measurement of the primary particle size (D1) according to an observation method, for example, an aqueous dispersion including 0.01% by mass of polishing particles is dropped on a copper microgrid and dried, subsequently particle images are obtained using a transmission electron microscope (H7650 manufactured by Hitachi High-Technologies Corp.) at a measurement magnification ratio of 20,000 times, and then a plurality of particle sizes is measured with an analysis software, Mac-View. Thus, the median value of the Heywood diameter can be measured as the primary particle size (D1). Furthermore, according to the BET specific surface area method, for example, a dispersion liquid of polishing particles is preliminarily dried on a hot plate and then heat-treated at 800° C., thus a sample for measurement is produced, and the BET specific surface area is measured using this sample for measurement. The primary particle size (D1) can be calculated from the true specific gravity and the specific surface area of the polishing particles.

The composition for treating a surface of semiconductor of the invention may not include polishing particles; however, in a case in which polishing particles are used, the content of the polishing particles is preferably 0.2% to 10% by mass, and more preferably 0.3% to 5% by mass, with respect to the total mass of the composition for treating a surface of semiconductor. When the content of the polishing particles is in the above-described range, a stable composition for treating a surface of semiconductor, with which a sufficient polishing speed for a wiring metal film can be obtained, and also, sedimentation and separation of particles do not easily occur, is likely to be obtained.

Examples of the water-soluble (co)polymer or a salt thereof include polymers of unsaturated carboxylic acids, such as poly(meth)acrylic acid and an acrylic acid-methacrylic acid copolymer, salts thereof; and water-soluble polymers such as polyvinyl alcohol, polyvinylpyrrolidone, and hydroxyethyl cellulose. These may be used singly, or two or more kinds thereof may be used in combination.

The content of the water-soluble (co)polymer or a salt thereof is preferably 0% to 1% by mass, and more preferably 0% to 0.5% by mass, with respect to the total mass of the composition for treating a surface of semiconductor.

Examples of the oxidizing agent include hydrogen peroxide; organic peroxides such as peracetic acid, perbenzoic acid, and tert-butyl hydroperoxide; permanganic acid compounds such as potassium permanganate; dichromic acid compound such as potassium dichromate; halogenic acid compounds such as potassium iodate; nitric acid compounds such as nitric acid and iron nitrate; perhalogenic acid compounds such as perchloric acid; persulfuric acid salts such as ammonium persulfate; and heteropolyacids. These may be used singly, or two or more kinds thereof may be used in combination.

In the case of using an oxidizing agent, the content of the oxidizing agent is preferably 0.01% to 30% by mass, more preferably 0.05% to 20% by mass, and particularly preferably 0.1% to 10% by mass, with respect to the total mass of the composition for treating a surface of semiconductor.

Examples of the reducing agent include amine-based reducing agents such as hydroxylamine, ydroxylamine sulfate, hydroxylamine hydrochloride, hydroxylamine nitrate, hydroxylamine phosphate, N,N-dimethylhydroxylamine, N,N-dimethylhydroxylamine sulfate, N,N-dimethylhydroxylamine hydrochloride, N,N-dimethylhydroxylamine nitrate, N,N-dimethylhydroxylamine phosphate, N,N-diethylhydroxylamine, N,N-diethylhydroxylamine sulfate, N,N-diethylhydroxylamine hydrochloride, N,N-diethylhydroxylamine nitrate, and N,N-diethylhydroxylamine phosphate; sulfurous acid, ammonium sulfite, potassium sulfite, sodium sulfite, ascorbic acid, ammonium ascorbate, potassium ascorbate, sodium ascorbate, thioglycolic acid, ammonium thioglycolate, potassium thioglycolate, sodium thioglycolate, and N-acetyl-L-cysteine. These may be used singly, or two or more kinds thereof may be used in combination.

The content of the reducing agent is preferably 0% to 10% by mass, more preferably 0% to 5% by mass, and particularly preferably 0% to 2.5% by mass, with respect to the total mass of the composition for treating a surface of semiconductor, in order to enhance desired effects of the invention.

Examples of the surfactant include an anionic surfactant and a nonionic surfactant.

Specific examples of the anionic surfactant include alkyl benzene sulfonic acids such as dodecyl benzene sulfonic acid; alkyl naphthalene sulfonic acids; alkyl sulfuric acid esters such as lauryl sulfuric acid; sulfuric acid esters of polyoxyethylene alkyl ethers, such as polyoxyethylene lauryl sulfuric acid; naphthalene sulfonic acid condensates; and lignin sulfonic acid. These anionic surfactants may also be used in the form of salts.

Specific examples of the nonionic surfactant include polyoxyethylene alkyl ethers such as polyoxyethylene lauryl ether, polyoxyethylene cetyl ether, polyoxyethylene stearyl ether, and polyoxyethylene oleyl ether; polyoxyethylene aryl ethers such as polyoxyethylene octyl phenyl ether and polyoxyethylene nonyl phenyl ether; sorbitan fatty acid esters such as sorbitan monolaurate, sorbitan monopalmitate, and sorbitan monostearate; and polyoxyethylene sorbitan fatty acid esters such as polyoxyethylene sorbitan monolaurate, polyoxyethylene sorbitan monopalmitate, and polyoxyethylene sorbitan monostearate.

The surfactants may be used singly, or two or more kinds thereof may be used in combination.

The content of the surfactant is not particularly limited; however, the content is preferably 0% to 1% by mass, and more preferably 0% to 0.1% by mass, with respect to the total mass of the composition for treating a surface of semiconductor.

In a case in which the concentrations of various components of the composition for treating a surface of semiconductor of the invention are adjusted to the concentration ranges described above, the various components may be directly incorporated so as to obtain the concentration ranges, or a composition in a state of being more concentrated than the concentration ranges described above is produced, and the composition may be diluted such that the concentrations of the various components would be in the ranges described above, by adding a water-based medium to the composition before being used for a treatment. The composition in a concentrated state can be produced by increasing the concentrations of the various components other than the solvent by removing the solvent while maintaining the proportions of the contents of the various components other than the solvent. The composition can also be produced by reducing the amount of addition of the solvent in advance.

Examples of the pH adjusting agent include inorganic acids such as hydrochloric acid, nitric acid, sulfuric acid, and phosphoric acid; hydroxides of alkali metals, such as sodium hydroxide, potassium hydroxide, rubidium hydroxide, and cesium hydroxide; and basic substances such as tetramethylammonium hydroxide (TMAH) and ammonia. The pH adjusting agents described above may be used singly, or two or more kinds thereof may be used in combination. The pH of the composition for treating a surface of semiconductor may be adjusted to the range that will be described below, by using the pH adjusting agents.

<pH of Composition for Treating a Surface of Semiconductor>

The pH value at 25° C. in the composition for treating a surface of semiconductor of the invention is preferably in the range of 1 to 12, more preferably in the range of 2 to 10, even more preferably in the range of 2 to 8.5, still more preferably in the range of 2 to 7, even more preferably in the range of 2 to 6, still more preferably in the range of 3 to 5.5, and particularly preferably in the range of 3 to 5.

When the pH is adjusted to the range described above, the occurrence of corrosion of a metal (particularly tungsten) wiring surface in particular is suppressed. Contaminations can also be reduced or eliminated more effectively. Furthermore, it is easier to maintain the speed of the polishing treatment.

On the other hand, the composition for treating a surface of semiconductor of the invention can suppress the occurrence of corrosion of a metal wiring surface even in a case in which the pH value at 25° C. is in the range of 8 to 10. As described in the Examples described below, when the pH is in this range, generally, corrosion occurs easily even if polyethyleneimine is used (see Comparative Example 11). However, in regard to the composition for treating a surface of semiconductor of the invention, surprisingly, the occurrence of corrosion of a metal wiring surface can be sufficiently suppressed even if the pH is in the range of 8 to 10.

The pH of the composition for treating a surface of semiconductor can be adjusted by mixing, for example, the above-mentioned organic acid-based chelating agent or the pH adjusting agent.

Here, the pH refers to the hydrogen-ion index, and the value may be measured using, for example, a commercially available pH meter.

<Use of Composition for Treating a Surface of Semiconductor>

As described in the Examples below, the composition for treating a surface of semiconductor of the invention has an effect that the composition is not likely to corrode metals such as metal wiring, and effectively reduces or eliminates contaminations from the surface of semiconductor when the composition is used for treatments such as polishing and cleaning. Furthermore, in a case in which the composition for treating a surface of semiconductor is used for a polishing treatment, the composition is not likely to decrease the polishing speed.

The reason why such effects are imparted is not clearly understood. The present inventors expect that when the component (A) is adsorbed to a metal surface of, for example, metal wiring, corrosion of the metal is suppressed continually to a large extent, and thus an excellent effect of reducing or eliminating contaminations effectively is obtained by combining such a component (A) with a component (B). Furthermore, it expects that since the component (A) is easily adsorbed particularly to tungsten, the composition for treating a surface of semiconductor of the invention is appropriate for a surface treatment of a semiconductor having a tungsten-including metal wiring.

Therefore, the composition for treating a surface of semiconductor of the invention is useful as a composition for a polishing treatment such as a lapping treatment (rough polishing treatment), a polishing treatment (finish polishing treatment), or a chemical mechanical polishing treatment (CMP treatment); a cleaning or peeling treatment such as an etching treatment, a cleaning treatment after a chemical mechanical polishing treatment, a peeling treatment of a photosensitive resin, or an ashing residue cleaning treatment of removing the ash of a photosensitive resin remaining on the surface of an ashed wafer; a flattening treatment of performing a polishing treatment and a cleaning treatment together; or a rinsing treatment of washing away after a cleaning treatment such as described above. Furthermore, since these treatments constitute a process in semiconductor production, the composition for treating a surface of semiconductor of the invention is useful even for a method for producing a semiconductor.

The composition for treating a surface of semiconductor of the invention is suitable as a composition for a polishing treatment and/or a cleaning treatment. Particularly, the composition for treating a surface of semiconductor is suitable as a composition for a chemical mechanical polishing treatment and/or a cleaning treatment after a chemical mechanical polishing treatment, and is especially suitable as a composition for a cleaning treatment after a chemical mechanical polishing treatment.

Meanwhile, it is preferable that the composition for treating a surface of semiconductor of the invention is liquid (including a slurry form).

The composition for treating a surface of semiconductor of the invention is adequate for a treatment of a surface including a metal (specifically, metal wiring) in a semiconductor substrate. Examples of the metal include tungsten, copper, cobalt, ruthenium, and titanium; however, the composition for treating a surface of semiconductor of the invention is especially suitable for a treatment of a surface including tungsten (for example, a surface including a metal wiring containing tungsten) in a semiconductor substrate.

The semiconductor surface may partially have an insulating film such as a silicon oxide film formed by a vacuum process.

[Method for Treating Semiconductor Surface]

The method for treating a surface of semiconductor of the invention is characterized by treating a surface of semiconductor with the composition for treating a surface of semiconductor of the invention described above.

Regarding a technique for treating a surface of semiconductor, a technique of bringing the composition for treating a surface of semiconductor of the invention into contact with a surface including a metal (specifically, metal wiring) of a semiconductor substrate, and treating the surface may be mentioned. Examples of the metal used for the metal wiring include tungsten, copper, cobalt, ruthenium, and titanium, similarly as described above. The method for treating a surface of semiconductor of the invention is especially suitable for a treatment of a tungsten-including semiconductor substrate (specifically speaking, a surface including a metal wiring containing tungsten in a semiconductor substrate).

Examples of the “treatment” according to the present method include, as described above, a polishing treatment such as a lapping treatment (rough polishing treatment), a polishing treatment (finish polishing treatment), or a chemical mechanical polishing treatment (CMP treatment); a cleaning or peeling treatment such as an etching treatment, a cleaning treatment after a chemical mechanical polishing treatment, a peeling treatment for a photosensitive resin, or an ashing residue cleaning treatment of removing ashes of a photosensitive resin remaining on an ashed wafer surface; a flattening treatment of performing a polishing treatment and a cleaning treatment together; and a rinsing treatment of washing away after the cleaning treatment such as described above. These treatments may be carried out in the same manner as in conventional methods, except that the composition for treating a surface of semiconductor of the invention is used.

Specific suitable examples of the method for treating a surface of semiconductor of the invention include the following methods 1 and 2.

(Method 1) A polishing treatment method for a surface of semiconductor, the method including a polishing process of subjecting a surface of semiconductor to a polishing treatment using the composition for treating a surface of semiconductor of the invention.

(Method 2) A cleaning treatment method for a surface of semiconductor, the method including a cleaning process of subjecting a surface of semiconductor to a cleaning treatment using the composition for treating a surface of semiconductor of the invention.

A method for subjecting a surface of semiconductor to a flattening treatment, the method including a polishing step of subjecting a surface of semiconductor to a polishing treatment using the composition for treating a surface of semiconductor of the invention; and a cleaning step of subjecting, after the polishing step, the semiconductor surface to a cleaning treatment using the composition for treating a surface of semiconductor of the invention, is also included in the method for treating a surface of semiconductor of the present invention. In this method, cleaning with ultrapure water or pure water may be carried out before and after the cleaning step of using the composition for treating a surface of semiconductor.

In the following description, a specific example of a process for producing a wiring substrate by utilizing this method will be explained in detail with reference to the drawings.

(Polishing Step)

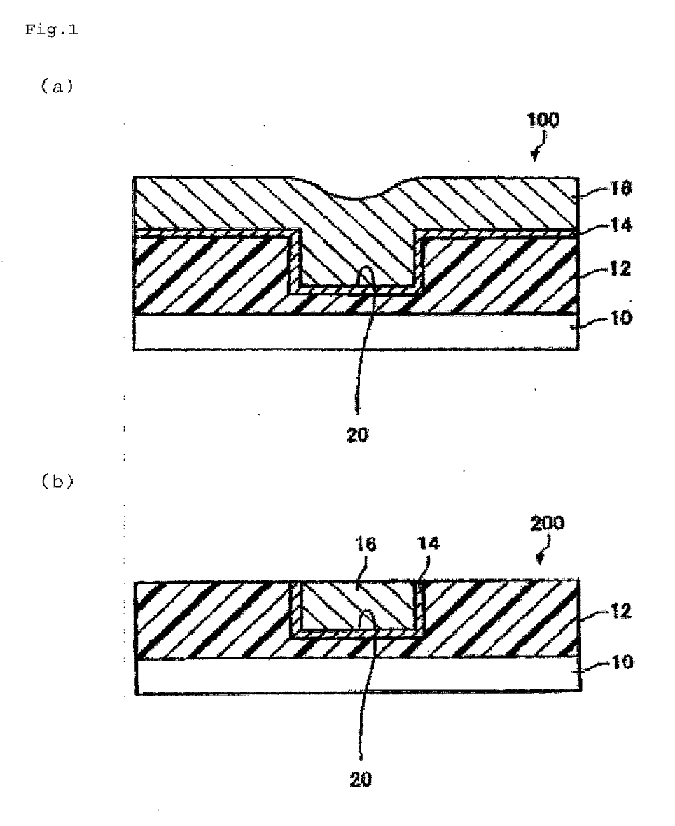

FIG. 1 is a cross-sectional view schematically illustrating a process for producing a wiring substrate by utilizing the method for treating a surface of semiconductor of the invention. Such a wiring substrate is formed by carrying out the following processes.

FIG. 1A is a cross-sectional view schematically illustrating an object to be treated before a chemical mechanical polishing (CMP) treatment.

As illustrated in FIG. 1A, an object to be treated 100 has a base body 10. The base body 10 may be configured to include, for example, a silicon substrate and a silicon oxide film formed thereon. Furthermore, although is not illustrated, the base body 10 may have a functional device such as a transistor formed thereon.

The object to be treated 100 is configured to include, on a base body 10, an insulating film 12 provided with concavities for wiring 20; a barrier metal film 14 provided so as to cover the surface of the insulating film 12 and the bottom and inner wall surfaces of the concavities for wiring 20; and a metal film 16 formed on the barrier metal film 14 to fill the concavities for wiring 20, all laminated in sequence.

Examples of the insulating film 12 include a silicon oxide film formed by a vacuum process (for example, a PETEOS film (Plasma Enhanced-TEOS film), a HDP film (High Density Plasma Enhanced-TEOS film), or a silicon oxide film obtainable by a thermochemical gas phase vapor deposition method), an insulating film called FSG (Fluorine-doped silicate glass), a borophosphosilicate film (BPSG film), an insulating film called SioN (Silicon oxynitride), and silicon nitride.

Examples of the barrier metal film 14 include tantalum, titanium, cobalt, ruthenium, manganese, and compounds thereof. The barrier metal film 14 is formed from one kind of these in many cases; however, two or more kinds thereof, such as tantalum and tantalum nitride, can be used in combination.

As shown in FIG. 1A, it is necessary that the metal film 16 completely embeds the concavities for wiring 20. In order to do so, a metal film having a thickness of 10,000 to 15,000 angstroms is deposited usually by a chemical vapor deposition method or an electroplating method. Examples of the material for the metal film 16 include tungsten, copper, cobalt, ruthenium, and titanium, and alloys are also acceptable.

Next, in the object to be treated 100 shown in FIG. 1A, the metal film 16 other than the parts embedded in the concavities for wiring 20 is subjected to high-speed polishing by CMP until the barrier metal film 14 is exposed (first polishing step). Furthermore, the barrier metal film 14 exposed to the surface is polished by CMP (second polishing step). In this manner, a wiring substrate 200 as illustrated in FIG. 1B is obtained. The composition for treating a surface of semiconductor of the invention may be used in the first polishing step or in the second polishing step. When a wiring substrate in which a wiring material and a barrier metal material co-exist on the surface is polished with the composition for treating a surface of semiconductor of the invention, corrosion of the wiring material and the barrier metal material can be suppressed, and any oxide film or organic residue on the wiring substrate can be efficiently reduced or eliminated.

(Cleaning Step)

Next, the surface (surface to be cleaned) of the wiring substrate 200 shown in FIG. 1B is cleaned using the composition for treating a surface of semiconductor of the invention. In this manner, corrosion of the wiring material and the barrier metal material can be suppressed even in a case in which the wiring substrate in which the wiring material and the barrier metal material co-exist on the surface is cleaned after completion of CMP, and any oxide film or organic residue on the wiring substrate can be efficiently reduced or eliminated.

The cleaning step is not particularly limited; however, this step is carried out by a technique of bringing the composition for treating a surface of semiconductor of the invention into direct contact with the wiring substrate 200. Examples of the method of bringing the composition for treating a surface of semiconductor into direct contact with the wiring substrate 200 include a dipping method of filling a cleaning bath with the composition for treating a surface of semiconductor and dipping the wiring substrate therein; a spinning method of rotating the wiring substrate at a high speed while causing the composition for treating a surface of semiconductor to flow down from a nozzle onto the wiring substrate; and a spraying method of cleaning the wiring substrate by spraying the composition for treating a surface of semiconductor onto the wiring substrate. Examples of apparatuses for performing these methods include a batch type cleaning apparatus for simultaneously cleaning a plurality of sheets of wiring substrate accommodated in a cassette; and a sheet type cleaning apparatus for mounting one sheet of wiring substrate on a holder and performing cleaning.

In regard to the method for treating a surface of semiconductor of the invention, the temperature of the composition for treating a surface of semiconductor of the invention at the time of performing the treatment is usually room temperature; however, the composition may be warmed to an extent that does not impair the performance, and for example, the composition can be warmed to about 40° C. to 70° C.

In addition to the method of bringing the composition for treating a surface of semiconductor of the invention into direct contact with the wiring substrate 200, it is also preferable to use a cleaning method of utilizing a physical force in combination. Thereby, the removability of contaminations by the particles adhering to the wiring substrate 200 is enhanced, and the cleaning time can be shortened. Examples of the method of cleaning by a physical force include scrub cleaning using a cleaning brush, and ultrasonic cleaning.

### EXAMPLES

Hereinafter, the present invention will be described in detail by way of Examples; however, the invention is not intended to be limited to these Examples.

The abbreviations for the raw materials used in the Examples are as follows.

DAMA: Dimethylaminoethyl methacrylate

MMA: Methyl methacrylate

nBMA: Normal butyl methacrylate

EHMA: 2-Ethyl hexyl methacrylate

[Conditions for Measurement of Mw and Mw/Mn]

Mw and Mn measured in the respective Synthesis Examples are values measured by gel permeation chromatography under the following conditions and calculated relative to polystyrene standards.

Apparatus: GPC-104 (manufactured by Showa Denko K.K.)

Column: Three LF-604 columns and one KF-602 column were connected and used.

Mobile phase: THF

Temperature: 40° C.

Flow rate: 0.6 mL/min

### Synthesis Examples 1 to 3: Synthesis of Particular Polymer (1)

Polymers were synthesized in the same manner as in Synthesis Examples 1 to 3 of WO 2017/104676.

That is, random copolymers a-1, a-2, and a-3, each having an epoxy group at the chain ends and having repeating units derived from DAMA, MMA, nBMA, and EHMA, were obtained. By using these, polymers each having repeating units derived from DAMA, MMA, nBMA, and EHMA in a polyethyleneimine side chain and having a portion thereof converted to quaternary ammonium were synthesized. The polymers thus obtained will be referred to as Polymers (A-1), (A-2), and (A-3).

### Synthesis Example 4: Synthesis of Particular Polymer (2)

A polymer was synthesized in the same manner as in Synthesis Example 4 of WO 2017/104676.

That is, a random copolymer a-4 having an epoxy group at the chain ends and having repeating units derived from DAMA, MMA, nBMA, and EHMA was obtained. By using this, a polymer having a partial structure derived from phenyl biguanide and repeating units derived from DAMA, MMA, nBMA, and EHMA and having a portion thereof converted to quaternary ammonium was synthesized. The polymer thus obtained will be referred to as Polymer (A-4).

### Synthesis Example 5: Synthesis of Particular Polymer (3)

A polymer was synthesized in the same manner as in Synthesis Example 5 of WO 2017/104676.

That is, a random copolymer a-5 having an epoxy group at the chain ends and having repeating units derived from DAMA, MMA, nBMA, and EHMA was obtained. By using this, a polymer having a partial structure derived from 1-(o-tolyl) biguanide and repeating units derived from DAMA, MMA, MMA, nBMA, and EHMA and having a portion thereof converted to quaternary ammonium was synthesized. The polymer thus obtained will be referred to as Polymer (A-5).

The copolymerization proportions (mass %) of various monomers and the content proportion (parts by mass) of epichlorohydrin with respect to 100 parts by mass of the total amount of monomers with regard to the polymer a-1 to polymer a-5 obtained in Synthesis Examples 1 to 5 are presented in Table 1.

Furthermore, Mw and Mw/Mn of polymer a-1 to polymer a-5 are also shown in Table 1.

TABLE 1

| | Polymer | Polymer | Polymer | Polymer | Polymer |
|---|---|---|---|---|---|
| | a-1 | a-2 | a-3 | a-4 | a-5 |
| DAMA (mass %) | 60.0 | 70.0 | 60.0 | 60.0 | 60.0 |
| MMA (mass %) | 15.0 | 11.0 | 15.0 | 15.0 | 15.0 |
| nBMA (mass %) | 10.0 | 8.0 | 10.0 | 10.0 | 10.0 |
| EHMA(mass %) | 15.0 | 11.0 | 15.0 | 15.0 | 15.0 |
| Total of repeating | 100 | 100 | 100 | 100 | 100 |
| units (mass %) | | | | | |
| Epichlorohydrin | 7.2 | 7.2 | 7.0 | 7.2 | 7.2 |
| (parts by mass) | | | | | |
| Mw | 2020 | 1980 | 2480 | 2020 | 2020 |
| Mw/Mn | 1.21 | 1.23 | 1.25 | 1.21 | 1.21 |

Table 2 shows the polymers that provided the polymer chains used in Synthesis Examples 1 to 5 (polymer a-1 to polymer a-5), the compounds that provided the particular partial structures, and the use ratios of benzyl chloride.

TABLE 2

| | Syn- | Syn- | Syn- | Syn- | Syn- |
|---|---|---|---|---|---|
| | thesis | thesis | thesis | thesis | thesis |
| | Exam- | Exam- | Exam- | Exam- | Exam- |
| | ple 1 | ple 2 | ple 3 | ple 4 | ple 5 |
| | (A-1) | (A-2) | (A-3) | (A-4) | (A-5) |
| Polymer a-1 to Polymer | 40 | 40 | 40 | 40 | 40 |
| a-5 (parts by mass) | | | | | |
| PEI300 (parts by mass) | 7.0 | — | 4.7 | — | — |
| PEI600 (parts by mass) | — | 13.9 | — | — | — |
| Phenyl biguanide (parts | — | — | — | 5.4 | — |
| by mass) | | | | | |
| 1-(o-tolyl) biguanide | — | — | — | — | 5.8 |
| (parts by mass) | | | | | |
| Benzyl chloride (parts by | 11.5 | 16.3 | 11.5 | 11.5 | 11.5 |
| mass) | | | | | |
| Relative to DAMA (eq) | 0.8 | 0.9 | 0.8 | 0.8 | 0.8 |

PEI300: manufactured by Junsei Chemical Co., Ltd., product name “POLYETHYLENEIMINE 300”
PEI600: manufactured by Junsei Chemical Co., Ltd., product name: “POLYETHYLENEIMINE 600”

### Examples 1 to 17 and Comparative Examples 1 to 12: Preparation of Compositions for Treating a Surface of Semiconductor (1)

Each of the compositions for treating a surface of semiconductor of Examples 1 to 17 and Comparative Examples 1 to 12 was obtained by introducing the components described in Table 3 or 4 (except for the pH adjusting agent) into a container made of polyethylene, adding nitric acid or potassium hydroxide thereto as a pH adjusting agent in order to obtain the pH value described in Table 3 or 4, and stirring mixture for 15 minutes.

### Examples 18 to 30 and Comparative Examples 13 to 21: Preparation of Compositions for Treating a Surface of Semiconductor (2)

Each of the compositions for treating a surface of semiconductor of Examples 18 to 30 and Comparative Examples 13 to 21 was obtained by introducing the components described in Table 5 or 6 (except for the pH adjusting agent) into a container made of polyethylene, adding nitric acid or potassium hydroxide thereto as a pH adjusting agent in order to obtain the pH value described in Table 5 or 6, and stirring the mixture for 15 minutes.

### Test Example 1: Measurement of Polishing Speed

A substrate for measuring the polishing speed (8-inch wafer for evaluation) as described in the following section (1) was subjected to chemical mechanical polishing under the conditions of the following section (2) on a chemical mechanical polishing apparatus, “EPO112” (manufactured by Ebara Corp.), by using each of the compositions for treating a surface of semiconductor of Examples 18 to 30 and Comparative Examples 13 to 21 as slurries for chemical mechanical polishing. The polishing speeds were calculated by the method of the following section (3). It can be said that a larger measured value of the polishing speed means superior polishing performance. The results are presented in Tables 5 and 6.

(1) Substrate for Measuring Polishing Speed
An 8-inch thermal oxide film-attached silicon substrate having a tungsten (W) film having a film thickness of 2,000 angstroms laminated thereon.
An 8-inch silicon substrate having a PETEOS film having a film thickness of 10,000 angstroms laminated thereon.

(2) Polishing Conditions
Speed of head rotation: 70 rpm
Load on head: 200 gf/cm²
Speed of table rotation: 70 rpm
Rate of supply of composition for treating a surface of semiconductor: 200 mL/min
Polishing time: 60 seconds

(3) Method for Calculating Polishing Speed

For a tungsten film, the film thickness after a polishing treatment was measured using an electrical conductivity type film thickness measuring machine (manufactured by KLA Tencor Corp., Model “OMNIMAP RS75”), and the polishing speed was calculated from the film thickness reduced by chemical mechanical polishing and the polishing time.

For a PETEOS film, the film thickness after a polishing treatment was measured using a light interference type film thickness measuring machine (manufactured by Nanometrics Japan, Ltd., Model “Nanospec 6100”), and the polishing speed was calculated from the film thickness reduced by chemical mechanical polishing and the polishing time.

### Test Example 2: Calculation of Etching Rate

An 8-inch silicon wafer having a film of cobalt (Co), tungsten (W), or PETEOS formed on the surface by a sputtering method was cut into a size of 1×3 cm, and this was used as a metal wafer specimen. For the specimens thus obtained, the film thicknesses were measured in advance using a metal film thickness meter, “RG-5”, manufactured by NPS, Inc. 100 mL each of the compositions for treating a surface of semiconductor contained in a polyethylene container was maintained at 60° C., and a metal wafer specimen having a film of cobalt or tungsten formed thereon was immersed in each of the compositions of Examples 1 to 17 and Comparative Examples 1 to 12, while a metal wafer specimen having a film of tungsten or PETEOS formed thereon was immersed in each of the compositions of Examples 18 to 30 and Comparative Examples 13 to 21, for 60 minutes in each case. Subsequently, the metal wafer specimens were cleaned with flowing water for 10 seconds and dried. The film thickness of each of the metal wafer specimen after the present immersion treatment was measured again, and the etching rate (ER, unit: A/min) was calculated by dividing the amount of reduced film thickness by 60 minutes of the immersion time. The results are presented in Tables 3 to 6.

### Test Example 3: Evaluation of Observation of Corrosion

An 8-inch silicon wafer having a film of cobalt (Co) or tungsten (W) formed on the surface by a sputtering method was cut into a size of 1×1 cm, and this was used as a metal wafer specimen. For the specimens thus obtained, the surface was observed using a scanning electron microscope at a magnification ratio of 50,000 times. 50 mL each of the compositions for treating a surface of semiconductor of Examples 1 to 17 and Comparative Examples 1 to 12 was introduced into a polyethylene container and maintained at 25° C., and a metal wafer specimen (1×1 cm) was immersed therein for 60 minutes. The metal wafer specimen was cleaned with flowing water for 10 seconds and dried, and then corrosion of the surface was observed using a scanning electron microscope at a magnification ratio of 50,000 times. Thus, the corrosion of the surface was evaluated according to the following criteria. The results are presented in Tables 3 and 4.

(Evaluation Criteria for Observation of Corrosion)

A: No shape change in the surface caused by corrosion was recognized, compared to the state prior to immersion.

B: Sites where corrosion had occurred and sites where corrosion did not occur existed in a mixed manner, compared to the state prior to immersion.

C: The entire surface had been corroded, compared to the state prior to immersion.

### Test Example 4-1: Evaluation of Defects (1)

A cleaning treatment after chemical mechanical polishing was carried out using each of the compositions for treating a surface of semiconductor of Examples 1 to 17 and Comparative Examples 1 to 12, and an evaluation on defects made in this treatment was performed. The specific procedure is as follows.

First, an aqueous dispersion of colloidal silica, PL-3 (manufactured by Fuso Chemical Co., Ltd.) was introduced into a container made of polyethylene, in an amount corresponding to 1% by mass in terms of silica, and ion-exchanged water was added to the container such that the total amount of all the constituent components would be 100% by mass. Maleic acid was added thereto as a pH adjusting agent to adjust the pH value to 3. Furthermore, a 35 mass % aqueous solution of hydrogen peroxide was added to the container as an oxidizing agent in an amount corresponding to 1% by mass in terms of hydrogen peroxide, and the mixture was stirred for 15 minutes. Thus, composition for chemical mechanical polishing X was obtained.

An 8-inch silicon wafer having a film of cobalt (Co) or tungsten (W) formed on the surface by a sputtering method was cut into a size of 3×3 cm, and this was used as a metal wafer specimen. This metal wafer specimen was used as an object to be polished, and a chemical mechanical polishing treatment was performed for one minute under the following polishing conditions.

(Polishing Conditions)

Polishing apparatus: “LM-15C” manufactured by Lapmaster SFT Corp.

Polishing pad: “IC1000/K-Groove” manufactured by Rodel Nitta Co.

Speed of polishing table rotation: 90 rpm

Speed of head rotation: 90 rpm

Head pressing pressure: 3 psi

Rate of supply of composition for chemical mechanical polishing X: 100 mL/min

Subsequently, a water cleaning treatment on a polishing pad was performed for 10 seconds under the cleaning conditions in which the rate of supply of ion-exchanged water was 500 mL/min. Each of metal wafer specimens that had been treated by chemical mechanical polishing by the present method was observed at five sites in a frame size of 10 m using Dimension FastScan, which is a scanning atomic force microscope (AFM) manufactured by Bruker Corporation. Only those metal wafer specimens which could be confirmed to have a flat surface, with the average value of the arithmetic mean roughness of the five sites being 0.1 nm or less, were selected and used for a subsequent evaluation of defects. 50 mL each of the compositions for treating a surface of semiconductor of Examples 1 to 17 and Comparative Examples 1 to 12 was kept warm at 25° C., and the specimens selected as described above were immersed in this composition for 15 minutes. The specimens were cleaned with flowing water for 10 seconds and dried, and then an observation was made at any five sites in a frame size of 10 μm using AFM. Five sheets of images thus obtained were analyzed by using an image analysis software program, and the total of adhering materials having a height of 2.0 nm or more was designated as the number of defects. The evaluation criteria were as follows. The number of defects and the evaluation results are presented in Tables 3 and 4.

(Evaluation Criteria for Number of Defects (1))

A: The number of defects was less than 100.

B: The number of defects was 100 or more and less than 500.

C: The number of defects was 500 or more.

### Test Example 4-2 Evaluation of Defects (2)

A chemical mechanical polishing treatment was performed using each of the compositions for treating a surface of semiconductor of Examples 18 to 30 and Comparative Examples 13 to 21 as a composition for chemical mechanical polishing, and an evaluation on defects made in this treatment was performed. The specific procedure was as follows.

An 8-inch silicon wafer having a film of tungsten (W) formed on the surface by a sputtering method was cut to a size of 3×3 cm, and this was used as a metal wafer specimen. This metal wafer specimen was used as an object to be polished, and a chemical mechanical polishing treatment was carried out for one minute under the following polishing conditions.

(Polishing Conditions)

Polishing apparatus: “LM-15C” manufactured by Lapmaster SFT Corp.

Polishing pad: “IC1000/K-Groove” manufactured by Rodel Nitta Co.

Speed of polishing table rotation: 90 rpm

Speed of head rotation: 90 rpm

Head pressing pressure: 3 psi

Rate of supply of composition for chemical mechanical polishing: 100 mL/min

Subsequently, a water cleaning treatment on a polishing pad was performed for 10 seconds under the cleaning conditions in which the rate of supply of ion-exchanged water was 500 mL/min. Each of metal wafer specimens that had been treated by chemical mechanical polishing by the present method was observed at five sites in a frame size of 10 μm using Dimension FastScan, which is a scanning atomic force microscope (AFM) manufactured by Bruker Corporation. Five sheets of images thus obtained were analyzed by using an image analysis software program, and the total of adhering materials having a height of 10 nm or more was designated as the number of defects. The evaluation criteria were as follows. The number of defects and the evaluation results are presented in Tables 5 and 6.

(Evaluation Criteria for Number of Defects (2))

A: The number of defects was less than 30.

B: The number of defects was 30 or more and less than 150.

C: The number of defects was 150 or more.

TABLE 3

| | | Example | | | | | | | | |
|---|---|---|---|---|---|---|---|---|---|---|
| Concentration (mass %) | | 1 | 2 | 3 | 4 | 5 | 6 | 7 | 8 | 9 |
| Component | Polymer (A-1) | 0.05 | 0.01 | 0.01 | 0.01 | 0.01 | 0.01 | 0.01 | 0.005 | 0.01 |
| (A) | Polymer (A-2) | — | — | — | — | — | — | — | — | — |
| | Polymer (A-3) | — | — | — | — | — | — | — | — | — |
| | Polymer (A-4) | — | — | — | — | — | — | — | — | — |
| | Polymer (A-5) | — | — | — | — | — | — | — | — | — |
| Component | Citric acid | 0.02 | 0.1 | 0.1 | 0.1 | — | — | — | — | — |
| (B) | Malic acid | — | — | — | — | 0.005 | 0.02 | 0.2 | — | — |
| | EDTA(*1) | — | — | — | — | — | — | — | 0.02 | 0.02 |
| | Histidine | — | — | — | — | — | — | — | — | — |
| | Monoethanolamine | — | — | — | — | — | — | — | — | — |
| pH | Nitric acid | Proper | Proper | Proper | — | Proper | — | — | — | — |
| adjusting | | amount | amount | amount | | amount | | | | |
| agent | Potassium hydroxide | — | — | — | Proper | — | Proper | Proper | Proper | Proper |
| | | | | | amount | | amount | amount | amount | amount |
| Other | Aqueous hydrogen | — | — | — | — | 1 | — | — | — | — |
| components | peroxide | | | | | | | | | |
| | Hydroxylamine | — | — | — | — | — | — | 4 | — | — |
| | Polyethyleneimine(*2) | — | — | — | — | — | — | — | — | — |
| | (Mw = 600) | | | | | | | | | |
| | Ion-exchanged water | Balance | Balance | Balance | Balance | Balance | Balance | Balance | Balance | Balance |

| | | | | | | | | | |
|---|---|---|---|---|---|---|---|---|---|
| Total | 100 | 100 | 100 | 100 | 100 | 100 | 100 | 100 | 100 |
| pH (25° C.) | 2.5 | 3.2 | 1.0 | 11.0 | 2.5 | 5.0 | 8.0 | 6.0 | 6.0 |

Evaluation results

| | | | | | | | | | | |
|---|---|---|---|---|---|---|---|---|---|---|
| W | PER [Å/min.] | 0.2 | 0.4 | 0.2 | 8.6 | 0.9 | 0.2 | 3.9 | 1.2 | 0.9 |
| | Evaluation of | A | A | A | B | A | A | A | A | A |
| | corrosion (SEM) | | | | | | | | | |
| | Evaluation of defects | 59 | 31 | 20 | 23 | 5 | 22 | 61 | 30 | 32 |
| | (AFM) | A | A | A | A | A | A | A | A | A |
| Co | ER [Å/min.] | 3.5 | 6.1 | 9.8 | 0.1 | 9.4 | 1.7 | 0.3 | 3.5 | 3.5 |
| | Evaluation of | A | B | B | A | B | A | A | A | A |
| | corrosion (SEM) | | | | | | | | | |
| | Evaluation of defects | 130 | 72 | 359 | 297 | 322 | 65 | 6 | 74 | 90 |
| | (AFM) | B | A | B | B | B | A | A | A | A |

| | | Example | | | | | | | |
|---|---|---|---|---|---|---|---|---|---|
| Concentration (mass %) | | 10 | 11 | 12 | 13 | 14 | 15 | 16 | 17 |
| Component | Polymer (A-1) | 0.05 | 0.05 | — | — | — | — | — | — |
| (A) | Polymer (A-2) | — | 0.01 | 0.0005 | — | — | — | — | — |
| | Polymer (A-3) | — | — | — | — | 0.01 | — | — | — |
| | Polymer (A-4) | — | — | — | — | — | 0.01 | — | — |
| | Polymer (A-5) | — | — | — | — | — | — | 0.001 | 0.001 |
| Component | Citric acid | — | — | — | — | — | — | — | — |
| (B) | Malic acid | — | — | — | — | — | — | — | — |
| | EDTA(*1) | 0.02 | 0.02 | — | — | — | — | — | — |
| | Histidine | — | — | 0.02 | — | — | — | 0.02 | 0.02 |
| | Monoethanolamine | — | — | — | 0.02 | 0.02 | 0.02 | — | — |
| pH | Nitric acid | Proper | — | — | — | — | Proper | Proper | Proper |
| adjusting | | amount | | | | | amount | amount | amount |
| agent | Potassium hydroxide | — | Proper | Proper | Proper | Proper | — | — | — |
| | | | amount | amount | amount | amount | | | |
| Other | Aqueous hydrogen | 1 | — | — | — | — | — | 1 | — |
| components | peroxide | | | | | | | | |
| | Hydroxylamine | — | 1 | — | — | — | — | — | — |
| | Polyethyleneimine(*2) | — | — | — | — | — | — | — | — |
| | (Mw = 600) | | | | | | | | |
| | Ion-exchanged water | Balance | Balance | Balance | Balance | Balance | Balance | Balance | Balance |
| Total | | 100 | 100 | 100 | 100 | 100 | 100 | 100 | 100 |
| pH (25° C.) | | 2.5 | 9.5 | 8.0 | 9.0 | 9.0 | 3.0 | 5.0 | 8.0 |
| Evaluation results | | | | | | | | | |
| W | ER [Å/min.] | 0.9 | 3.6 | 3.3 | 3.9 | 2.7 | 0.4 | 2.5 | 4.4 |
| | Evaluation of | A | A | A | A | A | A | A | A |
| | corrosion (SEM) | | | | | | | | |
| | Evaluation of defects | 27 | 56 | 45 | 34 | 10 | 59 | 15 | 56 |
| | (AFM) | A | A | A | A | A | A | A | A |
| Co | ER [Å/min.] | 8.8 | 0.8 | 0.2 | 0.3 | 0.1 | 0.1 | 2.8 | 0.5 |
| | Evaluation of | B | A | A | A | A | A | A | A |
| | corrosion (SEM) | | | | | | | | |
| | Evaluation of defects | 88 | 37 | 44 | 20 | 34 | 23 | 40 | 21 |
| | (AFM) | A | A | A | A | A | A | A | A |

(*1)Ethylenediamine tetraacetate,
(*2)“POLYETHYLENEIMINE 600” manufactured by Junsei Chemical Co., Ltd.

TABLE 4

| | | Comparative Example | | | | | | | | | | | |
|---|---|---|---|---|---|---|---|---|---|---|---|---|---|
| Concentration (mass %) | | 1 | 2 | 3 | 4 | 5 | 6 | 7 | 8 | 9 | 10 | 11 | 12 |
| Component | Polymer (A-1) | 0.05 | — | — | — | — | — | — | — | — | — | — | — |
| (A) | Polymer (A-2) | — | 0.001 | — | — | — | — | — | — | — | — | — | — |
| | Polymer (A-3) | — | — | 0.01 | — | — | — | — | — | — | — | — | — |
| | Polymer (A-4) | — | — | — | 0.01 | — | — | — | — | — | — | — | — |
| | Polymer (A-5) | — | — | — | — | 0.01 | — | — | — | — | — | — | — |
| Component | Citric acid | — | — | — | — | — | 0.02 | — | — | — | — | — | 0.02 |
| (B) | Malic acid | — | — | — | — | — | — | — | — | — | — | 0.01 | — |
| | Ethylenediamine | — | — | — | — | — | — | 0.02 | — | — | — | — | — |
| | tetraacetate | | | | | | | | | | | | |
| | Histidine | — | — | — | — | — | — | — | 0.02 | — | — | — | — |
| | Monoethanolamine | — | — | — | — | — | — | — | — | 0.1 | — | — | — |
| pH | Nitric acid | Proper | — | — | Proper | Proper | Proper | — | Proper | Proper | Proper | — | Proper |
| adjusting | | amount | | | amount | amount | amount | | amount | amount | amount | | amount |
| agent | Potassium | — | Proper | Proper | — | — | — | Proper | — | — | — | Proper | — |
| | hydroxide | | amount | amount | | | | amount | | | | amount | |
| Other | Aqueous | — | — | — | — | 1 | — | — | — | — | — | — | — |
| components | hydrogen | | | | | | | | | | | | |
| | peroxide | | | | | | | | | | | | |
| | Hydroxylamine | — | — | — | — | — | — | — | — | 4 | — | 4 | — |
| | Polyethyl- | — | — | — | — | — | — | — | — | — | 0.10 | 0.05 | 0.10 |
| | eneimine(*2) | | | | | | | | | | | | |
| | (Mw = 600) | | | | | | | | | | | | |
| | Ion- | Balance | Balance | Balance | Balance | Balance | Balance | Balance | Balance | Balance | Balance | Balance | Balance |
| | exchanged | | | | | | | | | | | | |
| | water | | | | | | | | | | | | |

| | | | | | | | | | | | | |
|---|---|---|---|---|---|---|---|---|---|---|---|---|
| Total | 100 | 100 | 100 | 100 | 100 | 100 | 100 | 100 | 100 | 100 | 100 | 100 |
| pH (25° C.) | 2.5 | 8.0 | 9.0 | 3.0 | 5.0 | 25 | 8.0 | 4.0 | 8.0 | 2.5 | 9.0 | 2.5 |

Evaluation results

| | | | | | | | | | | | | | |
|---|---|---|---|---|---|---|---|---|---|---|---|---|---|
| W | ER [Å/min.] | 0.1 | 4.2 | 4.8 | 0.2 | 3.4 | 22.7 | 35.1 | 24.2 | 44.9 | 9.3 | 18.5 | 10.8 |
| | Evaluation | A | A | A | A | B | C | C | C | C | B | C | B |
| | of | | | | | | | | | | | | |
| | corrosion | | | | | | | | | | | | |
| | (SEM) | | | | | | | | | | | | |
| | Evaluation | 913 | 778 | 947 | 1148 | 662 | 93 | 28 | 89 | 84 | 798 | 399 | 1009 |
| | of | C | C | C | C | C | A | A | A | A | C | B | C |
| | defects | | | | | | | | | | | | |
| | (AFM) | | | | | | | | | | | | |
| Co | ER [Å/min.] | 10.3 | 2.4 | 0.2 | 7.8 | 12.5 | 12.4 | 5.5 | 14.6 | 9.3 | 11.9 | 4.1 | 16.6 |
| | Evaluation | C | B | A | B | B | B | A | C | C | C | A | C |
| | of | | | | | | | | | | | | |
| | corrosion | | | | | | | | | | | | |
| | (SEM) | | | | | | | | | | | | |
| | Evaluation | 697 | 991 | 732 | 776 | 663 | 1157 | 890 | 934 | 1017 | 1161 | 981 | 1034 |
| | of | C | C | C | C | C | C | C | C | C | C | C | C |
| | defects | | | | | | | | | | | | |
| | (AFM) | | | | | | | | | | | | |

(*2)“POLYETHYLENEIMINE 600” manufactured by Junsei Chemical Co., Ltd.

TABLE 5

| | | Example | | | | | | |
|---|---|---|---|---|---|---|---|---|
| Concentration (mass %) | | 18 | 19 | 20 | 21 | 22 | 23 | 24 |
| Component (A) | Polymer (A-1) | 0.10 | 0.02 | 0.02 | 0.02 | 0.02 | 0.01 | 0.02 |
| | Polymer (A-2) | — | — | — | — | — | — | — |
| | Polymer (A-3) | — | — | — | — | — | — | — |
| | Polymer (A-4) | — | — | — | — | — | — | — |
| | Polymer (A-5) | — | — | — | — | — | — | — |
| Component (B) | Citric acid | 0.02 | 0.1 | 0.1 | — | — | — | — |
| | Malic acid | — | — | — | 0.005 | 0.1 | — | — |
| | Ethylenediamine tetraacetate | — | — | — | — | — | 0.1 | 0.1 |
| | Histidine | — | — | — | — | — | — | — |
| | Monoethanolamine | — | — | — | — | — | — | — |
| pH adjusting agent | Nitric acid | Proper | Proper | Proper | Proper | — | — | — |
| | | amount | amount | amount | amount | | | |
| | Potassium hydroxide | — | — | — | — | Proper | Proper | Proper |
| | | | | | | amount | amount | amount |
| Other components | Polyethyleneimine(*2) | — | — | — | — | — | — | — |
| | (Mw = 600) | | | | | | | |
| | Aqueous hydrogen peroxide | 1 | 0.1 | 1 | 1 | 1 | 0.5 | 1 |
| | Abrasive grains(*3) | 2.5 | 2.5 | 2.5 | 2.5 | 2.5 | 2.5 | 2.5 |
| | Ion-exchanged water | Balance | Balance | Balance | Balance | Balance | Balance | Balance |

| | | | | | | | |
|---|---|---|---|---|---|---|---|
| Total | 100 | 100 | 100 | 100 | 100 | 100 | 100 |
| pH (25° C.) | 2.5 | 1.0 | 3.2 | 2.5 | 5.0 | 6.0 | 6.0 |

Evaluation results

| | | | | | | | | |
|---|---|---|---|---|---|---|---|---|
| W | ER [Å/min.] | 3.3 | 0.4 | 4.5 | 3.7 | 4.6 | 5.7 | 4.8 |
| | Polishing speed [Å/min.] | 160 | 150 | 180 | 170 | 230 | 240 | 240 |
| | Evaluation of defects (AFM) | 8 | 29 | 25 | 23 | 3 | 19 | 4 |
| | | A | A | A | A | A | A | A |
| PETEOS | ER [Å/min.] | 0.0 | 0.0 | 0.0 | 0.0 | 0.3 | 0.9 | 0.9 |
| | Polishing speed [Å/min.] | 440 | 370 | 390 | 440 | 380 | 430 | 370 |

| | | Example | | | | | |
|---|---|---|---|---|---|---|---|
| Concentration (mass %) | | 25 | 26 | 27 | 28 | 29 | 30 |
| Component (A) | Polymer (A-1) | 0.1 | — | — | — | — | — |
| | Polymer (A-2) | — | 0.02 | 0.001 | — | — | — |
| | Polymer (A-3) | — | — | — | 0.02 | — | — |
| | Polymer (A-4) | — | — | — | — | 0.02 | — |
| | Polymer (A-5) | — | — | — | — | — | 0.005 |
| Component (B) | Citric acid | — | — | — | — | — | — |
| | Malic acid | — | — | — | — | — | — |
| | Ethylenediamine tetraacetate | — | — | — | — | — | 0.02 |
| | Histidine | 0.02 | 0.1 | — | — | — | — |
| | Monoethanolamine | — | — | 0.1 | 0.02 | 0.02 | — |
| pH adjusting agent | Nitric acid | Proper | — | — | — | Proper | Proper |
| | | amount | | | | amount | amount |
| | Potassium hydroxide | — | Proper | Proper | Proper | — | — |
| | | | amount | amount | amount | | |
| Other components | Polyethyleneimine(*2) | — | — | — | — | — | — |
| | (Mw = 600) | | | | | | |
| | Aqueous hydrogen peroxide | 1 | 1 | 1 | 1 | 1 | 1 |
| | Abrasive grains(*3) | 2.5 | 2.5 | 2.5 | 2.5 | 2.5 | 2.5 |
| | Ion-exchanged water | Balance | Balance | Balance | Balance | Balance | Balance |
| Total | | 100 | 100 | 100 | 100 | 100 | 100 |
| pH (25° C.) | | 2.5 | 8.0 | 9.0 | 9.0 | 3.0 | 8.0 |
| Evaluation results | | | | | | | |
| W | ER [Å/min.] | 2.6 | 5.8 | 4.1 | 6.6 | 3.5 | 5.1 |
| | Polishing speed [Å/min.] | 180 | 240 | 290 | 300 | 190 | 310 |
| | Evaluation of defects (AFM) | 18 | 3 | 23 | 25 | 27 | 29 |
| | | A | A | A | A | A | A |
| PETEOS | ER [Å/min.] | 0.0 | 0.8 | 1.1 | 0.9 | 0.1 | 0.6 |
| | Polishing speed [Å/min.] | 450 | 410 | 390 | 350 | 460 | 370 |

(*2)“POLYETHYLENEIMINE 600” manufactured by Junsei Chemical Co., Ltd.,
(*3)Colloidal silica (solid content of “PL-3” manufactured by Fuso Chemical Co., Ltd., primary particle size 35 nm)

TABLE 6

| | | Comparative Example | | | | | | | | |
|---|---|---|---|---|---|---|---|---|---|---|
| Concentration (mass %) | | 13 | 14 | 15 | 16 | 17 | 18 | 19 | 20 | 21 |
| Component (A) | Polymer (A-1) | 0.10 | — | — | — | — | — | — | — | — |
| | Polymer (A-2) | — | 0.02 | — | — | — | — | — | — | — |
| | Polymer (A-3) | — | — | 0.05 | — | — | — | — | — | — |
| | Polymer (A-4) | — | — | — | 0.02 | — | — | — | — | — |
| | Polymer (A-5) | — | — | — | — | 0.10 | — | — | — | — |
| Component (B) | Citric acid | — | — | — | — | — | 0.005 | — | — | 0.02 |
| | Malic acid | — | — | — | — | — | — | — | — | — |
| | Ethylenediamine tetraacetate | — | — | — | — | — | — | 0.005 | — | — |
| | Histidine | — | — | — | — | — | — | — | — | — |
| | Monoethanolamine | — | — | — | — | — | — | — | 0.02 | — |
| pH adjusting agent | Nitric acid | Proper | — | — | Proper | Proper | Proper | — | Proper | Proper |
| | | amount | | | amount | amount | amount | | amount | amount |
| | Potassium hydroxide | — | Proper | Proper | — | — | — | Proper | — | — |
| | | | amount | amount | | | | amount | | |
| Other components | Polyethyleneimine(*2) | — | — | — | — | — | — | — | — | 0.05 |
| | (Mw = 600) | | | | | | | | | |
| | Aqueous hydrogen peroxide | 1 | 0.75 | 0.75 | 0.1 | 1 | 1 | 1 | 2 | 1 |
| | Abrasive grains(*3) | 2.5 | 2.5 | 2.5 | 2.5 | 2.5 | 2.5 | 2.5 | 2.5 | 2.5 |
| | Ion-exchanged water | Balance | Balance | Balance | Balance | Balance | Balance | Balance | Balance | Balance |

| | | | | | | | | | |
|---|---|---|---|---|---|---|---|---|---|
| Total | 100 | 100 | 100 | 100 | 100 | 100 | 100 | 100 | 100 |
| pH (25° C.) | 2.5 | 8.0 | 9.0 | 3.0 | 5 | 2.5 | 8.0 | 4.0 | 2.5 |

Evaluation results

| | | | | | | | | | | |
|---|---|---|---|---|---|---|---|---|---|---|
| W | ER [Å/min.] | 1.3 | 4.2 | 4.7 | 0.3 | 4.5 | 13.4 | 34.3 | 11.8 | 7.5 |
| | Polishing speed [Å/min.] | 160 | 250 | 310 | 25 | 230 | 200 | 220 | 190 | 90 |
| | Evaluation of defects (AFM) | 192 | 234 | 288 | 223 | 204 | 96 | 21 | 24 | 262 |
| | | C | C | C | C | C | B | A | A | C |
| PETEOS | ER [Å/win.] | 0.0 | 0.2 | 2.2 | 0.0 | 0.3 | 0.0 | 0.7 | 0.1 | 0.0 |
| | Polishing speed [Å/min.] | 440 | 50 | 40 | 410 | 190 | 460 | 260 | 320 | 450 |

(*2)“POLYETHYLENEIMINE 600” manufactured by Junsei Chemical Co., Ltd.,
(*3)Colloidal silica (solid content of “PL-3” manufactured by Fuso Chemical Co., Ltd., primary particle size 35 nm)

As shown in Table 3, when compositions for treating a surface of semiconductor that included component (A) and component (B) in combination (Examples 1 to 17) was used for a cleaning treatment after chemical mechanical polishing, satisfactory results for the evaluation of defects were obtained for both tungsten and cobalt, and it found that contaminations can be effectively reduced or eliminated. Furthermore, it found from the results of the evaluation of corrosion obtained by ER measurement and SEM that the compositions are not likely to corrode metals. In addition, the compositions for treating a surface of semiconductor showed a tendency appropriate for a cleaning treatment of a semiconductor substrate including tungsten wiring.

Comparative Examples 1 to 5 in Table 4 were compositions for treating a surface of semiconductor that lacked of component (B). As shown in Table 4, when the compositions of Comparative Examples 1 to 5 were used for a cleaning treatment after chemical mechanical polishing, poor results for the evaluation of defects were obtained for both tungsten and cobalt, and contaminations could not be reduced or eliminated effectively.

Comparative Examples 6 to 9 of Table 4 were compositions for treating a surface of semiconductor that lacked component (A). As shown in Table 4, the compositions of Comparative Examples 6 to 9 resulted in large values of ER for tungsten (more than 10 Å/min) and were likely to corrode tungsten. Furthermore poor results for the evaluation of defects were obtained for cobalt.

Comparative Examples 10 to 12 of Table 4 were compositions for treating a surface of semiconductor that used polyethyleneimine instead of component (A). As shown in Table 4, the compositions of Comparative Examples 10 and 12 among these gave poor results for the evaluation of defects for both tungsten and cobalt, and thus, the compositions could not reduce or eliminate contaminations effectively. The composition of Comparative Example 11 resulted in a large value of ER for tungsten (more than 10 Å/min) and was likely to corrode tungsten. Furthermore, for all of Comparative Examples 10 to 12, poor results for the evaluation of defects were obtained for cobalt.

In this Table 4, it understood that when component (B) was added to the composition of Comparative Example 10 (Comparative Example 12), any improvement was hardly seen in the respective evaluations.

As shown in Table 5, when a chemical mechanical polishing treatment was performed using compositions for treating a surface of semiconductor that included component (A) and component (B) in combination (Examples 18 to 30), satisfactory results for the evaluation of defects were obtained, and it found that contaminations could be effectively reduced or eliminated. Furthermore, it found from the results of ER measurement that the compositions were not likely to corrode metals.

It also found from Tables 3 and 5 that the combination of component (A) and component (B) is widely useful for treating a surface of semiconductors such as polishing and cleaning.

Comparative Examples 13 to 17 of Table 6 were compositions for treating a surface of semiconductor that lacked component (B). As shown in Table 6, when a chemical mechanical polishing treatment was performed using the compositions of Comparative Examples 13 to 17, poor results for the evaluation of defects were obtained, and contaminations could not be reduced or eliminated effectively.

Comparative Examples 18 to 20 of Table 6 were compositions for treating a surface of semiconductor that lacked component (A). As shown in Table 6, the compositions of Comparative Examples 18 to 20 resulted in large values of ER for tungsten (more than 10 Å/min) and were likely to corrode tungsten.

Comparative Example 21 of Table 6 was a composition for treating a surface of semiconductor that included polyethyleneimine, instead of component (A), in combination with component (B). As shown in Table 6, when a chemical mechanical polishing treatment was performed using the composition of Comparative Example 21, poor results for the evaluation of defects were obtained, and contaminations could not be reduced or eliminated effectively.

What is claimed is:

1. A composition for treating a surface of semiconductor, the composition comprising:
(A) a polymer having a polymer chain having a repeating unit represented by the following Formula (1); and
(B) a chelating agent having a molecular weight of 500 or less: 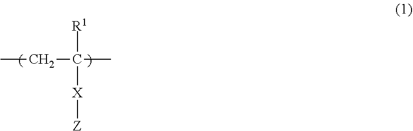
wherein R¹ represents a hydrogen atom or a methyl group; Z represents a group forming an organic ammonium salt, —NR⁵R⁶ (R⁵ and R⁶ each independently represent a hydrogen atom, or a substituted or unsubstituted hydrocarbon group), or a substituted or unsubstituted nitrogen-containing heterocyclic group; and X represents a single bond or a divalent linking group.

2. The composition according to claim 1, wherein the polymer (A) further has a partial structure derived from a compound containing a group represented by —NH—, provided that the polymer chain is excluded.

3. The composition according to claim 2, wherein the partial structure is a residue by removing a part of or all of hydrogen atoms derived from the group represented by —NH—, from the compound containing a group represented by —NH—.

4. The composition according to claim 1, wherein the chelating agent (B) is at least one selected from the group consisting of an organic amine-based chelating agent having a molecular weight of 500 or less, and an organic acid-based chelating agent having two or more carboxyl groups and having a molecular weight of 500 or less.

5. The composition according to claim 1, wherein the pH at 25° C. is 2 to 6.

6. The composition according to claim 1, wherein the pH at 25° C. is 8 to 10.

7. A method for treating a surface of semiconductor using the composition according to claim 1.

8. The method according to claim 7, wherein a substrate of the semiconductor is a tungsten-containing semiconductor substrate.
